(19) United States
(12) Patent Application Publication
(10) Pub. No.: US 2011/0042649 A1
(43) Pub. Date: Feb. 24, 2011

(54) Thin-Film Transistor, Carbon-Based Layer and Method of Producing Thereof

(75) Inventors: Steven Grant Duvall, Milsons Point (AU); Pavel Khokhlov, Moscow (RU); Pavel I. Lazarev, Menlo Park, CA (US)

Correspondence Address: HOUST CONSULTING (Kont), P.O. BOX 2688, SARATOGA, CA, 95070-0688, US

(73) Assignee: Carben Semicon Limited

(21) Appl. No.: 12/867,754

(22) PCT Filed: Feb. 16, 2009
(86) PCT No.: PCT/GB09/50146

§ 371 Date: Nov. 7, 2010

(30) Foreign Application Priority Data
Feb. 15, 2008 (GB) 0802912.6

(51) Int. Cl. H01L 51/10; B32B 3/00; B05D 5/12; B05D 3/10; B05D 3/02; B82Y 30/00

(52) U.S. Cl. 257/27; 257/29; 428/220; 427/122; 216/13; 427/228; 977/938; 257/E51.006; 977/762; 977/734

(57) ABSTRACT

The present invention relates to a thin-film transistor which comprises a conductive and predominantly continuous carbon-based layer (3) comprising predominantly planar graphene-like structures. The graphene-like structures may be in the following various forms: planar graphene-like nanoribbons oriented predominantly perpendicularly to the carbon-based layer surface or planar graphene-like sheets oriented predominantly parallel to the carbon-based layer surface. The carbon-based layer thickness is in the range from approximately 1 to 1000 nm.

The present invention relates to a thin-film transistor, and particularly to the carbon nanoribbons thin film transistor, which comprises a conductive and predominantly continuous carbon nanoribbons layer.

A typical thin-film transistor (hereinafter, referred to as TFT) comprises a number of layers which can be configured in various ways. For example, a TFT may comprise a substrate, an insulator layer, a semiconductor layer, a source electrode and a drain electrode connected to the semiconductor layer, and a gate electrode adjacent to the insulator layer. When a potential is applied to the gate electrode, charge carriers are accumulated in the semiconductor at its interface with the insulator. As a result, a conducting channel is formed between the source and the drain, in which a current flows when a potential difference is applied between the source and drain electrodes. In conventional TFTs, inorganic semiconductors such as Si or GaAs have been used as the channel materials.

At present, TFTs find use in a number of applications such as the active drive matrices for large area displays. However, TFTs employing inorganic materials are often difficult and expensive to manufacture because of the high-temperature processing and high vacuum conditions required for obtaining devices uniform over large areas. As for the production of TFTs of this type, a method for manufacturing TFT on a glass substrate by using amorphous silicon or polycrystalline silicon (polysilicon) films as the semiconductor layers is known. Amorphous silicon films can be obtained using a plasma chemical vapour deposition (CVD) process and polysilicon films are usually obtained using a CVD process at low pressures. However, using the plasma CVD process, it is difficult to obtain TFTs of sufficient uniformity and large area because of restrictions related to the production equipment and the difficulty of plasma control. Further, the system must be evacuated to a high vacuum before film deposition, which decreases throughput. According to the low-pressure CVD process, a film is produced by decomposing the initial gas at a relatively high temperature of 450-600° C. and, therefore, expensive glass substrates of high heat resistance must be used which is economically disadvantageous.

In the past decade, there has been growing interest in developing TFTs using organic materials (hereinafter, referred to as OTFT). Organic devices offer the advantage of structural flexibility, potentially much lower manufacturing costs, and the possibility of conducting low-temperature technological processes on large areas. To gain full advantage of organic devices, it is necessary to develop materials and processes based on effective coating methods to form the various elements of the OTFT. In order to achieve large currents and fast switching, the semiconductor should possess high carrier mobility. For this reason, significant effort has been concentrated on the development of organic semiconductor materials with high mobility. A review of the progress in the development of such organic semiconductor materials is published in the IBM Journal of Research & Development, 45(1) (2001).

A variety of organic materials have been designed, synthesized and characterized as p-type semiconductors in which the majority carriers are holes. Organic thin film transistor (OTFT) devices have been made using such materials. Among these, thiophene oligomers have been proposed as semiconducting materials in Garnier et al., Structural Basis for High Carrier Mobility in Conjugated Oligomers, Synth. Met., 45, 163 (1991). Benzodithiophene dimers are presented as organic semiconductor materials in J. Liquindanum et al., Benzodithiophene Rings as Semiconducting Building Blocks, Adv. Mater., 9, 36 (1997). Pentacene, which is a representative of polyacenes, is one of the most widely studied organic semiconductors and is described as a semiconducting material for OTFT devices in Dimitrakopoulos et al., Molecular Beam Deposited Thin Film of Pentacene for Organic Field-Effect Transistor Applications, J. Appl. Phys., 80, 2501-2508 (1996); Jackson et al., Pentacene Organic Thin-Film Transistors for Circuit and Display Applications, IEEE Trans. Electron Devices, 46, 1259-1263 (1999).

A number of organic π-conjugated materials have been used as the active layers in OTFTs [Current Opinion in Solid State & Materials Science, 2, 455-461 (1997); Chem. Phys., 227, 253-262 (1998)]. However, none of these materials have been found completely satisfactory for practical applications because they exhibit poor electrical performance, are difficult to process in large scale manufacture, and/or are not sufficiently robust to attacks by atmospheric oxygen and water, which results in short working life of the related devices. For example, pentacene has been reported to give a field effect mobility of 2×10⁻³ cm²V⁻¹s⁻¹ but only when deposited under high vacuum conditions [Synth. Metals, 41-43, 1127 (1991)]. A soluble precursor route has also been reported for pentacene which allows liquid processing, but this material requires subsequent heating at temperatures 140-180° C. in vacuum to form the active layer [Synth. Metals, 88, 37-55 (1997)]. The final performance of an OTFT formed using this process is very sensitive to the substrate and the conversion conditions, and has very limited usefulness in terms of a practical manufacturing process. Conjugated oligomers such as α-hexathiophene [Synth. Metals, 54, 435 (1993); Science, 265, 1684 (1994)] were also reported to possess a field effect mobility of 2×10⁻³−1.5×10⁻² m²V⁻¹s⁻¹, but only when deposited under high vacuum conditions. Some semiconducting polymers such as poly(3-hexylthiophene) [Appl. Phys. Lett., 53, 195 (1988)] can be deposited from solution but the deposits have been found unsatisfactory for practical applications. Borsenberger et al. [Jpn. J. Appl. Phys., Pt 2A, 34(12), L1597-L1598 (1995)] describe high mobility doped polymers comprising a bis(di-tolylaminophenyl)cyclohexane doped into a series of thermoplastic polymers, apparently of possible use as transport layers in xerographic photoreceptors. However, this paper does not show an advantage of application of such materials in OTFTs.

OTFT using a metal phthalocyanine is also known [Chem. Phys. Lett., 142, 103 (1987)]. However, a metal phthalocyanine is produced by a vacuum vapour deposition process and therefore this type of OTFT faces the same problems as OTFT formed in amorphous silicon as a large number of OTFT's must be produced simultaneously and homogeneously.

As referenced above, when a 7-conjugated polymer obtained by electrochemical synthesis or an organic compound obtained by vacuum vapour deposition process are used in the semiconductor layer of an OTFT, it is difficult to produce an OTFT on a large area substrate simultaneously and homogeneously, which is disadvantageous for the industrial applications. Further, even when no gate voltage is applied or even when the OTFT is in an off state, a relatively large current flows between the source electrode and the drain electrode and, as a result, the drain current on-off ratio (or the element switching ratio) is small so as to make use of the OTFT as a switching element problematic.

Another OTFT based on pentacene is known [Yen-Yi Lin, David J. Gundlach, et al., Pentacene-Based Organic Thin-Film Transistors, IEEE Trans. Electron Dev., 44(8), 1325-1331 (1997)]. A heavily—doped silicon wafer is used as a substrate and a 400-nm-thick oxide layer is thermally grown for use as the gate dielectric. A 50-nm pentacene active layer is deposited by thermal evaporation at 7×10⁻⁵ Pa after material purification by vacuum gradient sublimation. The devices are completed by evaporating a 50-nm gold layer through a shadow mask to form source and drain contacts and a 100-nm aluminium layer onto the wafer rear side to contact the gate. The OTFT has a channel length and width of 20 and 220 μm, respectively. The OTFT has a field effect mobility, equal to 0.62 cm²/(V s) in the saturation region at V_{DS}=80 V. It is obvious that said mobility is much less than mobility in known inorganic materials. Carrier transport in the field-induced channel in the organic semiconductor layer (pentacene, and perhaps in most similar organic semiconductor systems) is dominated by the difficulty of moving carriers from a molecule to the adjacent one because of disorder, defects, and chemical impurities that can form trapping states.

There are two main configurations of a mutual arrangement of source and drain contacts with respect to a semiconducting layer. If the source and drain are formed on the surface of the semiconducting layer, the configuration is called top-contact. In the other case, the organic semiconducting layer is deposited above the source and drain contacts. This configuration is called bottom-contact. Both configurations possess some advantages and disadvantages. In the top-contact case, the masking layer should be deposited on the organic semiconductor layer. The masking layer should contain open windows for applying electrodes to the source and drain. Then the masking layer should be removed. During all these operations the organic semiconductor layer is subjected to additional chemical actions. These actions may lead to degradation of the electrical properties of the semiconducting layer.

A process that allows the photolithographic patterning of the source and drain electrodes on the insulator before depositing a semiconductor layer is preferable. In this case, a semiconducting layer is not exposed to chemical reagents which are necessary for the photolithography stage. The performance of devices fabricated using such a process is similar to or better than that of top-contact devices. Nevertheless, such devices have disadvantages as well. If the vacuum-deposited organic semiconductor films of pentacene are grown on the metal contacts of source and drain, the crystal grain size is smaller than in films grown on insulating layers. The grain size is especially small on gold contacts. Thus, the crystal structure of pentacene at the electrode edge poses limitations on the performance of the bottom-contact OTFT. Right at the edge of the Au electrode, there is an area with very small crystals and hence a large number of grain boundaries. Grain boundaries contain many morphological defects, which in turn are linked to the creation of charge-carrier traps with energy levels lying in the bandgap. These defects can be considered as responsible for the reduced performance of bottom-contact pentacene-based OTFTs.

Much effort has been directed toward producing oriented (or ordered) organic semiconductor layers in order to improve carrier mobility. Wittmann and Smith [Nature, 352, 414 (1991)] describe a method for orienting (ordering) organic materials on an oriented poly(tetrafluoroethylene) substrate (PTFE). The oriented PTFE was obtained by sliding a bar of solid PTFE over a hot substrate. This technique is applied to use an oriented PTFE film as a substrate for depositing organic semiconductors in the manufacture of field effect transistors. The organic semiconductor also becomes oriented, which results in higher carrier mobility. The PTFE layer is deposited according to the technique after Wittmann and Smith, that is, by sliding solid PTFE on the hot substrate. However, this technique is difficult to apply on large areas.

A well-defined test structure of organic static-induction transistor (SIT) having regularly sized nano-apertures in the gate electrode has been fabricated by colloidal lithography using 130-nm-diameter polystyrene spheres as shadow masks during vacuum deposition (see, IEICE TRANS. ELECTRON., VOL.E89-C, No. 12 DECEMBER 2006, pp. 1765-1770). Transistor characteristics of individual nano-apertures, namely ‘nano-SIT,’ have been measured using a conductive atomic-force-microscope (AFM) probe as a movable source electrode. The position of the source electrode is found to be more important to increased current on/off ratio than the distance between source and gate electrodes. The experimentally obtained maximum on/off ratio was 710 (at V_{DS}=−4V, V_{GS}=0 and 2V) when a source electrode was fixed at the edge of gate aperture. The characteristics have been then analyzed using semiconductor device simulation by employing a strongly non-linear carrier mobility model in the CuPc layer. From the device simulation, the source current is found to be modulated not only by a saddle point potential in the gate aperture area but also by a pinch-off effect near the source electrode. According to the obtained results, a modified structure of organic SIT and an adequate acceptor concentration is proposed. The on/off ratio of the modified organic SIT is expected to be ˜100 times larger than that of a conventional one.

The fabrication of TFTs using oriented Si nanowire thin films or CdS nanoribbons as semiconducting channels was reported in Nature, v. 425, 18 Sep. 2003, pp 274-278. The authors show that high performance TFTs can be produced on various substrates, including plastics, using a low-temperature assembly process. This approach is general to a broad range of materials including high-mobility materials (such as InAs or InP). Individual semiconductor nanowires (NWs) and single-walled carbon nanotubes have been used for nanoscale field-effect transistors (FETs) with performance comparable to or exceeding that of the single-crystal materials. In particular, carrier mobility values of 300 cm² V⁻¹ s⁻¹ have been demonstrated for p-type Si NWs, 2,000-4,000 cm² V⁻¹ s⁻¹ for n-type InP NWs and up to 20,000 cm² V⁻¹ s⁻¹ for single-walled carbon nanotubes. In this paper nanomaterial-enabled electronics was taken in a new direction: the authors exploit nanomaterials not for the next generation of nanoelectronics, but for high-performance macroelectronics. For macroelectronic applications, a number of key transistor parameters, including transconductance, mobility, on/off ratio, threshold voltage, and subthreshold swing, dictate TFT performance. The authors assemble NWs into oriented NW thin films to yield a novel electronic substrate; this substrate is processed using standard methods to produce NW-TFTs with conducting channels formed by multiple parallel single-crystal NW paths. In such NW-TFTs, charge travels from source to drain within single crystals, thus ensuring high carrier mobility. p-type Si—NWs with controlled diameters using a previously core surrounded by an amorphous silicon oxide shell of 1-3 nm thickness were synthesized. The NWs were then dispersed into solution, and assembled onto the surface of the chosen substrate using a flow-directed alignment method to produce an oriented NW thin film. An investigation of the NW thin film shows that the film consists of a monolayer of NWs oriented in parallel with an average NW spacing of 500-1,000 nm. The NW spacing is controlled by varying the NW solution concentration and flow time. Other approaches (for example, a Langmuir-Blodgett film) may also be used to obtain nearly close-packed NW thin films. Oriented-NW deposition can readily be achieved over a 4-inch wafer and potentially at larger scales. The NW thin film was then processed using standard lithography followed by metallization to define source and drain electrodes and yield TFTs. For initial study, the TFTs had a simple back-gated device configuration on a silicon substrate, where underlying silicon was used as the back gate, 100-nm-thick silicon nitride (SiNx) as the gate dielectric, and Ti/Au film as the source and drain electrodes. Drain current (I_{DS}) versus drain—source voltage (V_{DS}) relations at various gate voltages (V_{GS}) for a NW-TFT show typical accumulation mode p-channel transistor behaviour, as I_{DS} increases linearly with V_{DS} at low V_{DS}, and saturates at higher V_{DS}. Upon application of negative V_{GS}, I_{DS} increases as the majority carrier (hole) density increases in the channel. Applying a positive V_{GS} depletes holes in the channel and turns the device off. The plot of −I_{Ds} versus V_{GS} at a constant V_{DS}=−1V shows little current when the V_{GS} is more positive than a threshold voltage (Vth), and I_{DS} increases nearly linearly when the V_{GS} increases in the negative direction. Extrapolation of the linear region results in a Vth of 0.45V.

Electronic properties of graphene (carbon) nanoribbons are studied [Applied Physics Letters 88, 142102, (2006)] and compared to those of carbon nanotubes. The nanoribbons are found to have qualitatively similar electron band structure, which depends on chirality but with a significantly narrower band gap. The low- and high-field mobilities of the nanoribbons are evaluated and found to be higher than those of carbon nanotubes for the same unit cell but lower at matched band gap or carrier concentration. Due to the inverse relationship between mobility and band gap, it is concluded that graphene nanoribbons operated as field-effect transistors must have band gaps <0.5 eV to achieve mobilities significantly higher than those of silicon and thus may be better suited for low power applications.

Carbon-based nanostructures promise near ballistic transport and are being intensively explored for device applications. The performance limits of carbon nanoribbon (CNR) field-effect transistors (FETs) and carbon nanotube (CNT) FETs were compared [Applied Physics Letters 89, 203107 (2006)]. The ballistic channel conductance and the quantum capacitance of the CNRFET are about a factor of 2 smaller than those of the CNTFET because of the different valley degeneracy factors for CNRs and CNTs. The intrinsic speed of the CNRFET is higher due to a larger average carrier injection velocity. The gate capacitance plays an important role in determining which transistor delivers a larger current.

The article [IEEE Electron Device Letters, v. 28, No. 8, August 2007, pp. 760-1-762] presents an atomistic 3-D simulation of graphene nanoribbon field-effect transistors (GNR-FETs), based on the selfconsistent solution of the 3-D Poisson and Schrödinger equations with open boundary conditions within the nonequilibrium Green's function formalism and a tight-binding Hamiltonian. With respect to carbon nanotube FETs, GNR-FETs exhibit comparable performance, reduced sensitivity to the variability of channel chirality, and similar leakage problems due to band-to-band tunneling. Acceptable transistor performance requires prohibitive effective nanoribbon width of 1-2 nm and atomistic precision that could in principle be obtained with periodic etch patterns or stress patterns.

In the case of polyaromatic molecules, it was shown that fusion process starts at about 500-700° C. [Fitzer, E., Mueller, K. and Schaeffer, W., In Chemistry and Physics of Carbon, Vol. 7, ed. P. L. Walker Jr., M. Dekker, New York, p. 237 (1971)]. For example the authors of articles [Christopher Chan, Gregory Crawford, Yuming Gao, Robert Hurt, Kengqing Jian, Hao Li, Brian Sheldon, Matthew Sousa, Nancy Yang, “Liquid crystal engineering of carbon nanofibers and nanotubes”, Carbon 43, 2431-2440 (2005); M. E. Sousa, S. G. Cloutier, K. Q. Jian, B. S. Weissman, R. H. Hurt, G. P. Crawford, “Patterning lyotropic liquid crystals as precursors for carbon nanotube arrays”, Applied Physics Letters 87, 173115 (2005)] used indandthrone disulfonate to obtain carbon nanotubes by carbonization process. They obtained ordered supramolecular structure due to capillary forces in porous alumina matrices. Then samples were heated slowly (at a rate of 4°/min) to 700° C. and the temperature held at 700° C. for 1 hour under ultrahigh-purity nitrogen. These operations allowed obtaining of tubular carbon structures. The walls of each tube consist of ordered parallel graphene sheets oriented perpendicularly to the tube axis.

In a first aspect, the present invention provides a thin film transistor comprising: a carbon-based layer, a system of electrically conductive source and drain electrodes being in contact with the carbon-based layer, and at least one electrically conductive gate electrode intended for control of an electric current between the source and the drain electrodes. Said carbon-based layer is electrically conductive layer. This carbon-based layer has thickness in the range from approximately 1 to 1000 nm and comprises predominantly planar graphene-like structures.

In a second aspect, the present invention provides a carbon-based layer, possessing conductivity and comprising predominantly planar graphene-like structures. The layer thickness is in the range from approximately 1 to 1000 nm.

In a third aspect, the present invention provides a method of producing a carbon-based layer. This method comprises the following steps: (a) application on a substrate of a solution of one 17-conjugated organic compound of the general structural formula I or a combination of such organic compounds:

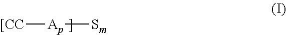

where CC is a predominantly planar carbon-conjugated core; A is an hetero-atomic group; p is 0, 1, 2, 3, 4, 5, 6, 7, or 8; Sₘ is a set of substituents providing a solubility of the organic compound; m is a number of S-type substituents in the set Sₘ which equals to 0, 1, 2, 3, 4, 5, 6, 7, or 8; b) drying with formation of a solid layer, and (c) formation of the carbon-based layer. Said formation processes are characterized by level of vacuum, composition and pressure of ambient gas, and time dependence of a temperature which are selected so as to ensure a creation of predominantly planar graphene-like structures in the carbon-based layer. At least one graphene-like structure possesses conductivity and is predominantly continuous within the entire carbon-based layer. The carbon-based layer thickness is in the range from approximately 1 to 1000 nm.

In a fourth aspect, the present invention provides a low-temperature method of producing a carbon-based layer on a substrate. This method comprises the following steps: a) preparation of a solution of one π-conjugated organic compound of the general structural formula II or a combination of such organic compounds capable of forming supramolecules:

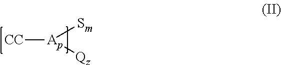

where CC is a predominantly planar carbon-conjugated core; A is an hetero-atomic group; p is 0, 1, 2, 3, 4, 5, 6, 7, or 8; S and Q are substituents; the substituent S is a substituent providing solubility of the organic compound in a suitable solvent and substituent Q is a substituent which produces reaction centres selected from the list comprising free radicals and benzyne fragments on the predominantly planar carbon-conjugated cores after elimination of this substituent during subsequent step (d); m is 0, 1, 2, 3, 4, 5, 6, 7, or 8; z is 0, 1, 2, 3 or 4;
(b) deposition of a layer of the solution on the substrate followed by external alignment action upon the solution in order to ensure preferred alignment of the supramolecules;
(c) drying to form a solid layer comprising graphene-like carbon-based structures; and
(d) applying an external action upon the solid layer stimulating carbonization of the graphene-like carbon-based structures.

In one embodiment of the disclosed thin film transistor, the graphene-like structures have the form of planar graphene-like nanoribbons which are predominantly continuous within the entire carbon-based layer. The planes of said nanoribbons are oriented predominantly perpendicularly to the carbon-based layer surface. In another embodiment of the disclosed thin film transistor, the graphene-like structures have form of planar graphene-like sheets which are predominantly continuous within the entire carbon-based layer. The planes of said sheets are oriented predominantly parallel to the carbon-based layer surface.

The carbon-based layer may have a thickness in the range from approximately 5 to 1000 nm.

In one embodiment of the present invention, the disclosed thin film transistor further comprises a substrate. In another embodiment of the present invention, the thin film transistor further comprises an insulator layer located between the carbon-based layer and at least one electrically conductive gate electrode. In still another embodiment of the disclosed thin film transistor, at least one electrically conductive gate electrode is located on the substrate; the insulator layer is located on said electrically conductive gate electrode and is in contact with them; the carbon-based layer is located on said insulator layer substantially overlapping with said gate electrodes; and the system of electrically conductive source and drain electrodes is located on said carbon-based layer and is in contact with this layer. In yet another embodiment of the disclosed thin film transistor, the system of electrically conductive source and drain electrodes is located on the substrate; the carbon-based layer is located on said source electrodes, drain electrodes and substrate and is in contact with them; the insulator layer is located on said carbon-based layer and is in contact with this layer; and the electrically conductive gate electrodes are located on said insulator layer and is in contact with this layer. In one embodiment of the disclosed thin film transistor, the electrically conductive gate electrodes are located on the substrate; the insulator layer is located on said electrically conductive gate electrodes and is in contact with them; the system of electrically conductive source and drain electrodes is located on said insulator layer and is in contact with this layer; and the carbon-based layer is located on said source electrodes, drain electrodes and insulator layer substantially overlapping with the gate electrodes. In another embodiment of the disclosed thin film transistor, the carbon-based layer is located on the substrate; the system of electrically conductive source and drain electrodes is located on said carbon-based layer and is in contact with this layer; the insulator layer is located on said source electrodes, drain electrodes and carbon-based layer and is in contact with them; and the electrically conductive gate electrodes are located on said insulator layer and is in contact with this layer.

In one embodiment of the disclosed thin film transistor, each of said systems of electrically conductive source and drain electrodes is aligned in relation to said gate electrodes. In another embodiment of the present invention, the thin film transistor further comprises an insulating passivation layer located on top of said transistor to protect the latter from further processing exposures and from the ambient factors. In still another embodiment of the disclosed thin film transistor, the substrate is made of one or several materials of the group comprising Si, Ge, SiGe, GaAs, diamond, quartz, silicon carbide, indium arsenide, indium phosphide, silicon germanium carbide, gallium arsenic phosphide, gallium indium phosphide, plastics, glasses, ceramics, metal-ceramic composites, metals, and comprises doped regions, circuit features, multilevel interconnects, and the carbon-based layer. In yet another embodiment of the disclosed thin film transistor, said plastic substrate is selected from the group comprising polycarbonate, Mylar, and polyimide.

In another embodiment of the disclosed thin film transistor, the width of the graphene-like nanoribbons provides the carbon-based layer with semiconductor properties due to the forming of an energy bandgap.

In one embodiment of the disclosed thin film transistor, the carbon-based layer possesses n-type conductivity. In this embodiment of the disclosed carbon nanoribbons thin film transistor, the gate electrodes are made of a material with a high electron work function. The material of said gate electrodes may be selected from the group comprising nickel, gold, platinum, lead, ITO, or combination thereof. In this embodiment of the disclosed thin film transistor, the source and drain electrodes are made of a material with a low electron work function. The material of said source and drain electrodes may be selected from the list comprising chromium, titanium, copper, aluminium, molybdenum, tungsten, indium, silver, calcium, and any combination thereof.

In yet another embodiment of the disclosed thin film transistor, the carbon-based layer possesses p-type conductivity. In this embodiment of the disclosed thin film transistor, the source and drain electrodes are made of a material with a low electron work function. The material of said source and drain electrodes may be selected from the list comprising chromium, titanium, copper, aluminium, molybdenum, tungsten, indium, silver, calcium, and any combination thereof. In this embodiment of the disclosed thin film transistor, the gate electrodes are made of a material of a high electron work function. The material of said gate electrodes may be selected from the list comprising nickel, gold, platinum, lead, ITO, and any combination thereof.

In another embodiment of the disclosed thin film transistor, the resistivity of the carbon-based layer material is in the range approximately from 1 to 10⁻⁷ Ohm*cm or less.

In still another embodiment of the disclosed thin film transistor, the gate electrodes are in the range between 30 nm and 500 nm thick and are produced by a process selected from the group comprising evaporation, sputtering, chemical vapour deposition, electrodeposition, spin coating, and electroless plating. In yet another embodiment of the disclosed thin film transistor, the material of said insulator layer is selected from the group comprising barium strontium titanate, barium zirconate titanate, lead zirconate titanate, lead lanthanum titanate, barium titanate, strontium titanate, barium magnesium fluoride, tantalum pentoxide, titanium dioxid, yttrium trioxide, silicon dioxide (SiO₂), silicon nitride (Si₃N₄), aluminium oxide (Al₂O₃), hafnium oxide (HfO₂), zirconium silicate, hafnium silicate, hafnium silicate oxynitride, titanium oxide, tantalum oxide, alumsilicate, carbon, carbon-doped silicon dioxide, and any combination thereof. In one embodiment of the disclosed thin film transistor, the insulator layer has a thickness in the range between approximately 1 and 1000 nm. In another embodiment of the disclosed thin film transistor, said insulator layer is produced by a process selected from the list comprising sputtering, chemical vapour deposition, sol gel coating, evaporation and laser ablation deposition.

In one embodiment of the disclosed thin film transistor, at least one electrically conductive gate electrode is the multilayer system comprising layers made of different conducting materials. In another embodiment of the disclosed thin film transistor, at least one electrically conductive source electrode is the multilayer system comprising layers made of different conducting materials. In still another embodiment of the disclosed thin film transistor, at least one electrically conductive drain electrode is the multilayer system comprising layers made of different conducting materials. In these embodiments of the disclosed thin film transistor, the conducting material may be selected from the list comprising copper, gold, silver, zinc, tin, indium, aluminium, titanium, poly-silicon, carbon-based layer as a semi-metal conductor, and any combination thereof.

In one embodiment of the disclosed thin film transistor, the carbon-based layer is made by the disclosed method of producing a carbon-based layer according to the third aspect of the present invention.

The present invention also provides the carbon nanoribbons layer as disclosed hereinabove. In one embodiment of the disclosed carbon-based layer, the graphene-like structures have the form of planar graphene-like nanoribbons which are predominantly continuous within the entire carbon-based layer. The planes of said nanoribbons are oriented predominantly perpendicularly to the carbon-based layer surface. In another embodiment of the disclosed carbon-based layer, the graphene-like structures have the form of planar graphene-like sheets which are predominantly continuous within the entire carbon-based layer. The planes of said sheets are oriented predominantly parallel to the carbon-based layer surface. In one embodiment of the present invention, the disclosed carbon-based layer possesses an optical anisotropy. In another embodiment of the present invention, the disclosed carbon-based layer possesses anisotropy of conductivity. In one embodiment of the disclosed carbon-based layer, the graphene-like structures are globally ordered within the entire carbon-based layer. In another embodiment of the disclosed carbon-based layer, a distance between planes of the graphene-like structures approximately equals to 3.5±0.1 Å. The carbon-based layer may have a thickness in the range from approximately 5 to 1000 nm.

In one embodiment of the present invention, the carbon-based layer is produced by the disclosed method according to the third aspect of the present invention.

The present invention also provides a method for producing the carbon-based layer, as disclosed hereinabove. In one embodiment of the disclosed method, the predominantly planar carbon-conjugated core (CC), the substituent providing solubility (S), and the S-substituent are selected so that the graphene-like structures have form of planar graphene-like nanoribbons the planes of which are oriented predominantly perpendicularly to the carbon-based layer surface. In another embodiment of the disclosed method, the predominantly planar carbon-conjugated core (CC), the substituent providing solubility (S), and the S-substituent are selected so that the graphene-like structures have form of planar graphene-like sheets the planes of which are oriented predominantly parallel to the carbon-based layer surface. In one embodiment of the disclosed method, the drying and formation steps are carried out simultaneously. In another embodiment of the disclosed method, the drying and formation steps are carried out sequentially. In still another embodiment of the disclosed method, the ambient gas comprises chemical elements selected from the list comprising hydrogen, fluorine, arsenic, boron, carbon tetrachloride, halogens, halogenated hydrocarbons, and any combination thereof. The carbon-based layer may have a thickness in the range from approximately 5 to 1000 nm.

In one embodiment of the present invention, the method further comprises a post-treatment in a gas atmosphere, wherein the post-treatment step is carried out after the formation step. In this embodiment of the disclosed method, the gas atmosphere for the post-treatment step comprises chemical elements selected from the list comprising hydrogen, fluorine, arsenic, boron, carbon tetrachloride, halogens, halogenated hydrocarbons, and any combination thereof.

In one embodiment of the present invention, the method further comprises a doping step carried out after the formation step and during which the carbon-based layer is doped with impurities. In another embodiment of the present invention, the method further comprises a doping step carried out after the post-treatment step and during which the carbon-based layer is doped with impurities.

In these embodiments of the present invention, the doping step is based on a diffusion method or ion implantation method. The impurity may be selected from the list comprising the following elements: Sb, P, As, Ti, Pt, Au, O, B, Al, Ga, In, Pd, S, F, N, and any combination thereof.

In one embodiment of the disclosed method, at least one of the hetero-atomic groups is selected from the list comprising imidazole group, benzimidazole group, amide group and substituted amide group. In another embodiment of the disclosed method, said solution is based on water. In still another embodiment of the disclosed method, at least one of the substituents providing a solubility of the organic compound is selected from the list comprising COO⁻, SO₃⁻, HPO₃⁻, and PO₃²⁻, and any combination thereof.

In one embodiment of the disclosed method, said solution is based on organic solvent. In this embodiment of the disclosed method, the organic solvent is selected from the list comprising ketones, carboxylic acids, hydrocarbons, cyclohydrocarbons, chlorohydrocarbons, alcohols, ethers, esters, and any combination thereof. The organic solvent is selected also from the list comprising acetone, xylene, toluene, ethanol, methylcyclohexane, ethyl acetate, diethyl ether, octane, chloroform, methylenechloride, dichloroethane, trichloroethene, tetrachloroethene, carbon tetrachloride, 1,4-dioxane, tetrahydrofuran, pyridine, triethylamine, nitromethane, acetonitrile, dimethylformamide, dimethulsulfoxide, and any combination thereof. At least one of the substituents providing a solubility of the organic compound in organic solvent may be selected from the list comprising linear and branched (C₁-C₃₅)alkyl, (C₂-C₃₅)alkenyl, and (C₂-C₃₅)alkinyl. In this embodiment of the disclosed method, the organic compound further comprises at least one bridging group B_{G} to provide a connection between at least one of the substituents providing a solubility of the organic compound in organic solvent and the predominantly planar carbon-conjugated core. At least one of the bridging groups B_{G} may be selected from the list, comprising —C(O)—, —C(O)O—, —C(O)—NH—, —(SO₂)NH—, —O—, —CH₂O—, —NH—, >N—, and any combination thereof.

In one embodiment of the disclosed method, at least one of the substituents providing a solubility of the organic compound is an amide of an acid residue independently selected from the list comprising CON R₁R₂, CONHCONH₂, SO₂NR₁R₂, R₃, and any combination thereof, where R₁, R₂ and R₃ are independently selected from the list comprising hydrogen, a linear alkyl group, a branched alkyl group, an aryl group, and any combination thereof, where the alkyl group has the general formula —(CH₂)ₙCH₃, where n is an integer from 0 to 27, and the aryl group is selected from the group comprising phenyl, benzyl and naphthyl.

In another embodiment of the disclosed method, said organic compound comprises rylene fragments. Examples of said organic compound comprising rylene fragments and having a general structural formula from the group comprising structures 1-24 are shown in the Table 1.

TABLE 1
Examples of organic compound with rylene fragments

| | |
|---|---|
| 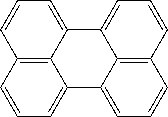 | 1 |
| 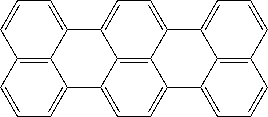 | 2 |
| 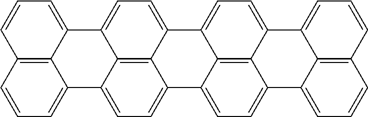 | 3 |
| 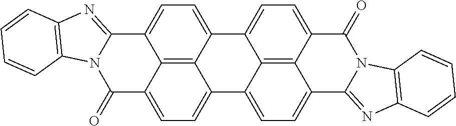 | 4 |
| 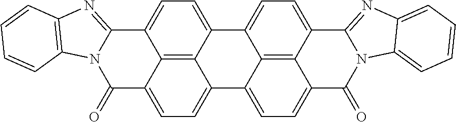 | 5 |
| 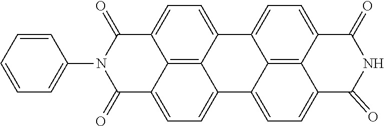 | 6 |
| 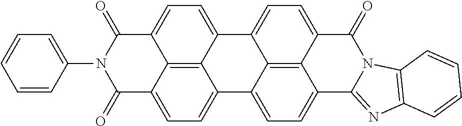 | 7 |
| 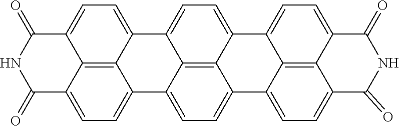 | 8 |
| 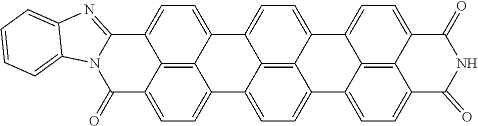 | 9 |
| 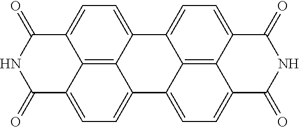 | 10 |
| 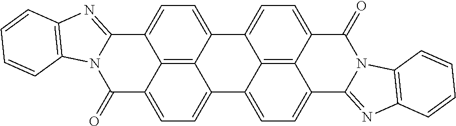 | 11 |
| 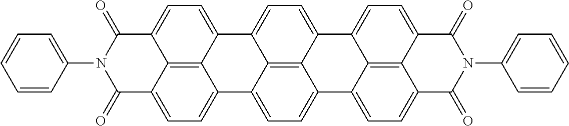 | 12 |
| 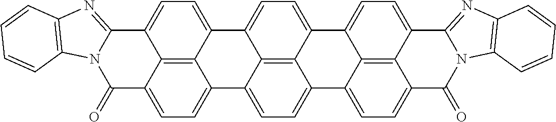 | 13 |
| 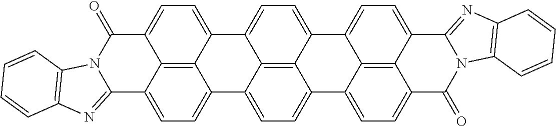 | 14 |
| 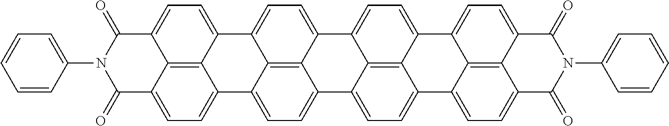 | 15 |
| 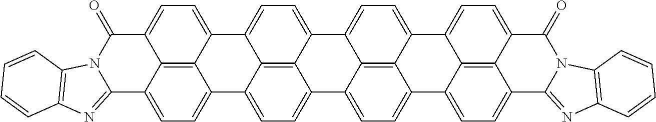 | 16 |
| 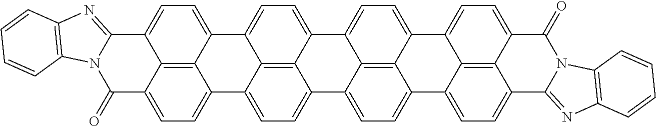 | 17 |
| 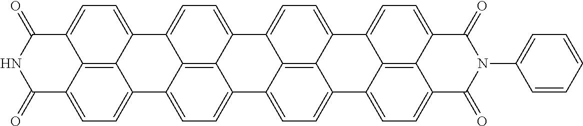 | 18 |
| 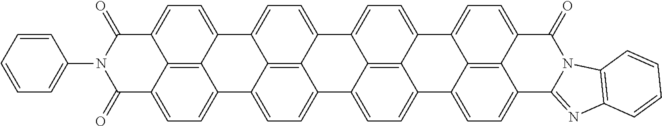 | 19 |
| 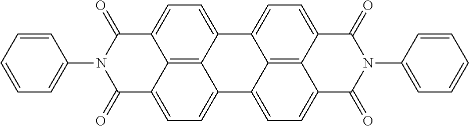 | 20 |
| 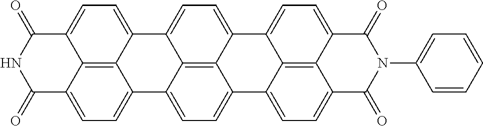 | 21 |
| 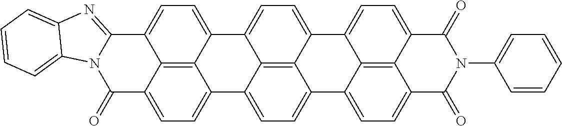 | 22 |
| 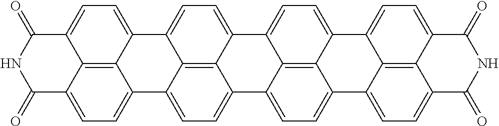 | 23 |
| 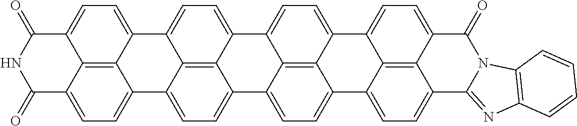 | 24 |

In still another embodiment of the disclosed method, said organic compound comprises anthrone fragments. Examples of said organic compound comprising anthrone fragments and having a general structural formula from the group comprising structures 25-36 are shown in the Table 2.

TABLE 2
Examples of organic compound with anthrone fragments

| | |
|---|---|
| 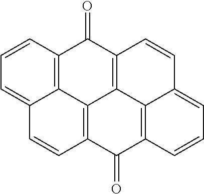 | 25 |
| 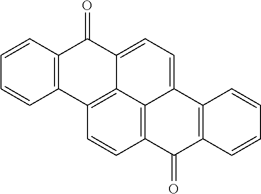 | 26 |
| 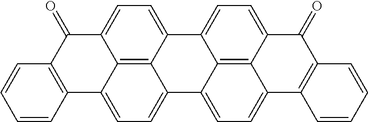 | 27 |
| 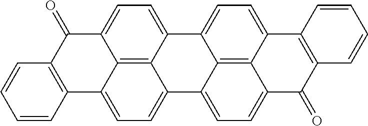 | 28 |
| 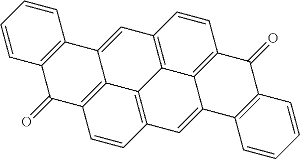 | 29 |
| 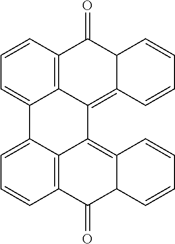 | 30 |
| 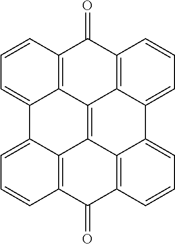 | 31 |
| 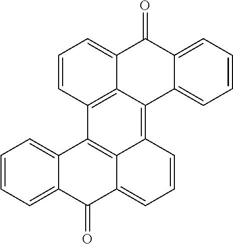 | 32 |
| 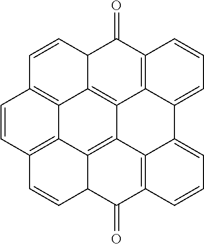 | 33 |
| 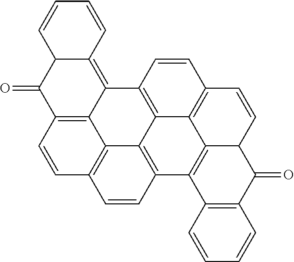 | 34 |
| 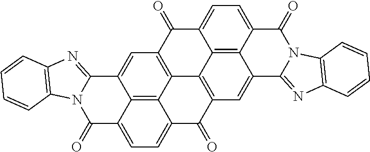 | 35 |
| 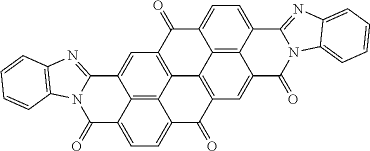 | 36 |

In yet another embodiment of the disclosed method, said organic compound comprises fused polycyclic hydrocarbons. Examples of said organic compound comprising fused polycyclic hydrocarbons and having a general structural formula from the group comprising structures 37-49 are shown in the Table 3. The fused polycyclic hydrocarbons are selected from the list comprising truxene, decacyclene, antanthrene, hexabenzotriphenylene, 1.2,3.4,5.6,7,8-tetra-(perinaphthylene)-anthracene, dibenzoctacene, tetrabenzoheptacene, peropyrene, hexabenzocoronene.

TABLE 3
Examples of organic compound with fused polycyclic hydrocarbons

| | |
|---|---|
| 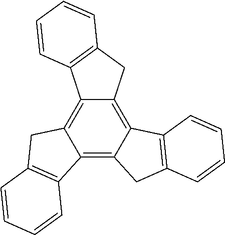 | 37 |
| 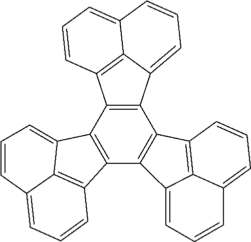 | 38 |
| 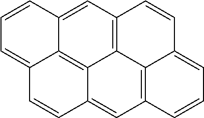 | 39 |
| 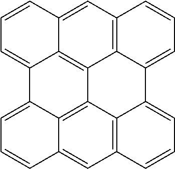 | 40 |
| 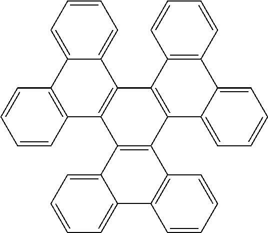 | 41 |
| 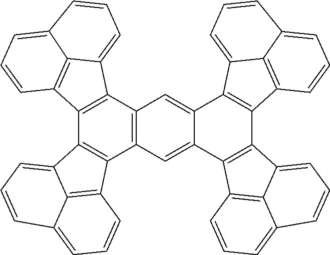 | 42 |
| 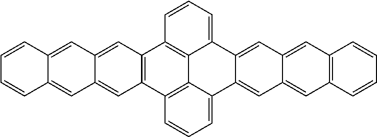 | 43 |
| 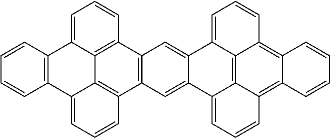 | 44 |
| 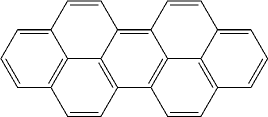 | 45 |
| 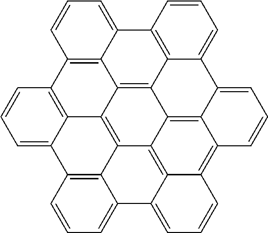 | 46 |
| 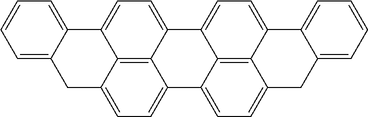 | 47 |
| 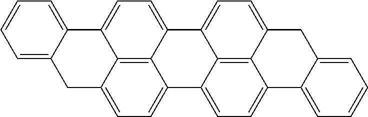 | 48 |
| 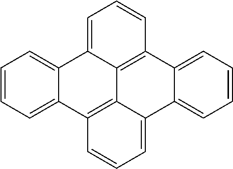 | 49 |

In one embodiment of the disclosed method, said organic compound comprises coronene fragments. Examples of said organic compound comprising coronene fragments and having a general structural formula from the group comprising structures 50-57 are shown in the Table 4.

TABLE 4
Examples of organic compound with coronene fragments

| | |
|---|---|
| 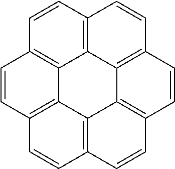 | 50 |
| 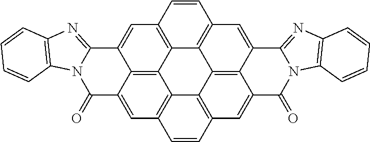 | 51 |
| 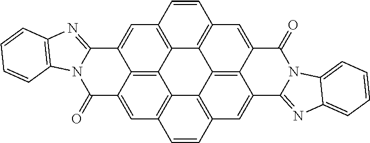 | 52 |
| 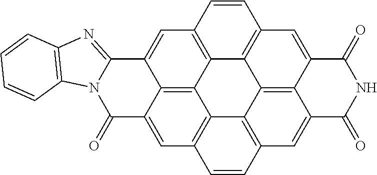 | 53 |
| 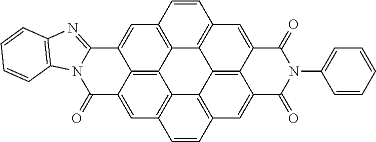 | 54 |
| 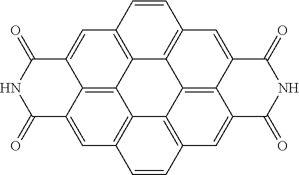 | 55 |
| 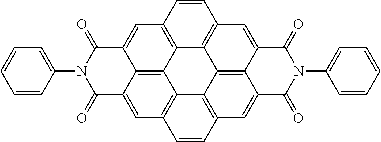 | 56 |
| 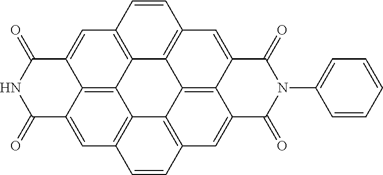 | 57 |

In another embodiment of the disclosed method, said organic compound comprises naphthalene fragments. Examples of said organic compound comprising naphthalene fragments and having a general structural formula from the group comprising structures 58-59 are shown in the Table 5.

TABLE 5
Examples of organic compound with naphthalene fragments

| | |
|---|---|
| 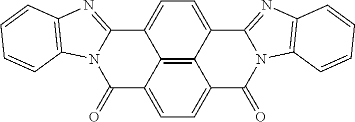 | 58 |
| 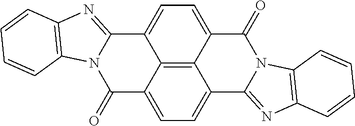 | 59 |

In still another embodiment of the disclosed method, said organic compound comprises pyrazine or/and imidazole fragments. Examples of said organic compound comprising pyrazine or/and imidazole fragments and having a general structural formula from the group comprising structures 60-65 are shown in the Table 6.

TABLE 6
Examples of organic compound with pyrazine or/and imidazole fragments

| | |
|---|---|
| 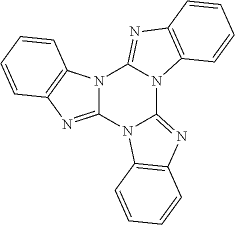 | 60 |
| 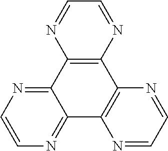 | 61 |
| 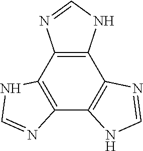 | 62 |
| 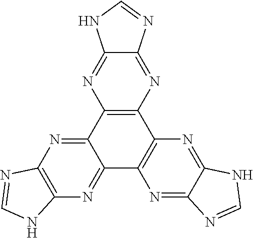 | 63 |
| 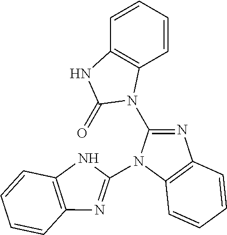 | 64 |
| 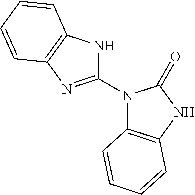 | 65 |

In one embodiment of the disclosed method, the drying stage is carried out using airflow. In another embodiment of the disclosed method, prior to the application of the solution the substrate is pretreated so as to render its surface hydrophilic.

In still another embodiment of the disclosed method, the solution is isotropic. In yet another embodiment of the disclosed method, said solution is a lyotropic liquid crystal solution. In one embodiment of the present invention, the method further comprises an alignment action, wherein the alignment action is simultaneous or subsequent to the application of said solution on the substrate. In another embodiment of the disclosed method, said application stage is carried out using a spray-coating. In still another embodiment of the disclosed method, said application stage is carried out using a Mayer rod technique or a slot-die application. In yet another embodiment of the disclosed method, said application stage is carried out using a printing.

In one embodiment of the disclosed method, the D-substituents further comprise molecular binding groups which number and arrangement thereof provide for the formation of planar supramolecules from the organic compound molecules in the solution via non-covalent chemical bonds. In this embodiment of the disclosed method, at least one binding group is selected from the list comprising a hydrogen acceptor (A_{H}), a hydrogen donor (D_{H}), and a group having the general structural formula:

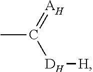

wherein the hydrogen acceptor (A_{H}) and hydrogen donor (D_{H}) are independently selected from the list comprising NH-group, and oxygen (O). At least one of the binding groups may be selected from the list comprising hetero-atoms, COOH, SO₃H, H₂PO₃, NH, NH₂, CO, OH, NHR, NR, COOMe, CONH₂, CONHNH₂, SO₂NH₂, —SO₂—NH—SO₂—NH₂, and any combination thereof, where radical R is independently selected from the list comprising a linear alkyl group, a branched alkyl group, and an aryl group, and any combination thereof, where the alkyl group has the general formula —(CH₂)ₙCH₃, where n is an integer from 0 to 27, and the aryl group is selected from the group comprising phenyl, benzyl and naphthyl.

In one embodiment of the disclosed method, the non-covalent chemical bonds are independently selected from the list comprising a single hydrogen bond, dipole-dipole interaction, cation—pi-interaction, Van-der-Waals interaction, coordination bond, ionic bond, ion-dipole interaction, multiple hydrogen bond, interaction via the hetero-atoms, and any combination thereof. In another embodiment of the disclosed method, the planar supramolecule have the form selected from the list comprising disk, plate, lamella, ribbon, and any combination thereof. In still another embodiment of the disclosed method, the planar supramolecules are predominantly oriented in the plane of the substrate.

In one embodiment of the disclosed method, the annealing is carried out in vacuum. In another embodiment of the disclosed method, the pyrolysis temperature is in the range between approximately 150 and 650 degrees C. In still another embodiment of the disclosed method, the fusion temperature is in the range between approximately 500 and 2000 degrees C. In still another embodiment of the disclosed invention the formation of carbon-based material is carried out under moderate heating or without heating (less than 500 degrees C.) under the action of gas-phase or liquid phase environment containing molecules which are sources of free radicals or benzyne fragments. In other embodiment of the disclosed invention the said process is further accompanied by applying an external action upon the solid layer stimulating low-temperature carbonization process of the graphene-like carbon-based structures.

In one embodiment of the disclosed method the formation step is carried out in vacuum, wherein the level of vacuum, the composition and pressure of ambient gas, the duration and temperature of the pyrolysis, the duration and temperature of the fusion, parameters of external actions (UV or IR light spectral characteristics) are selected so that the resistivity of the carbon-based layer material is in the range from approximately 1 to 10⁻³ Ohm*cm. In another embodiment of the disclosed method, the level of vacuum, the composition and pressure of ambient gas, the duration and temperature of the pyrolysis, the duration and temperature of the fusion, parameters of external actions (UV or IR light spectral characteristics) are selected so that the resistivity of the carbon-based layer material is in the range from approximately 10⁻³ to 10⁻⁵ Ohm*cm. In still another embodiment of the disclosed method, the level of vacuum, the composition and pressure of ambient gas, the duration and temperature of the pyrolysis, the duration and temperature of the fusion, parameters of external actions (UV or IR light spectral characteristics) are selected so that the resistivity of the carbon-based layer material is in the range from approximately 10⁻⁵ to 10⁻⁷ Ohm*cm. In yet another embodiment of the disclosed method, the level of vacuum, the composition and pressure of ambient gas, the duration and temperature of the pyrolysis, the duration and temperature of the fusion, parameters of external actions (UV or IR light spectral characteristics) are selected so that the resistivity of the carbon-based layer material is less than 10⁻⁷ Ohm*cm.

In one embodiment of the present invention, the method further comprises the step of removing the substrate by one of the methods selected from the list comprising wet chemical etching, dry chemical etching, plasma etching, laser etching, grinding, and any combination thereof. In another embodiment of the disclosed method, the set (Sₘ) comprises identical substituents providing solubility of the organic compound. In still another embodiment of the disclosed method, the set (Sₘ) comprises more than two substituents providing solubility of the organic compound and at least one substituent is different from the other or others. In yet another embodiment of the disclosed method, the steps (a), (b) and (c) are consistently repeated two or more times, and sequential carbon-based layers are formed using solutions based on the same or different organic compounds or their combinations.

In one embodiment of the disclosed method, at least one π-conjugated organic compound further comprises a set of substituents D_{Z}, wherein D is selected from a list comprising —NO₂, —Cl, —Br, —F, —CF₃, —CN, —OH, —OCH₃, —OC₂H₅, —OCOCH₃, —OCN, —SCN, —NH₂, —NHCOCH₃, and —CONH₂, and z is a number of D-type substituents and equals to 0, 1, 2, 3 or 4.

The present invention also provides the low-temperature method for producing the carbon-based layer, as disclosed hereinabove. In one embodiment of the disclosed method, the substituent Q is selected from the list comprising halogens Cl, Br, and I.

In another embodiment of the disclosed low-temperature method, the deposition step is carried out using a technique selected from the list comprising spray-coating, Mayer rod technique, slot-die application, extrusion, roll coating, curtain coating, knife coating, and printing.

In still another embodiment of the disclosed low-temperature method, the external alignment action upon the surface of the solution layer is produced by directed mechanical motion of at least one aligning instrument selected from the list comprising a knife, a cylindrical wiper, a flat plate and any other instrument oriented parallel to the deposited solution layer surface, whereby the distance from the substrate surface to the edge of the aligning instrument is preset so as to obtain a solid layer comprising graphene-like carbon-based structures of a required thickness. In yet another embodiment of the disclosed method, the external alignment action is performed using means selected from the list comprising a heated instrument, application of an external electric field to the deposited solution layer, application of an external magnetic field to the deposited solution layer, application of an external electric and magnetic field to the system, with simultaneous heating, and illuminating the deposited solution layer with at least one coherent laser beam.

In one embodiment of the disclosed low-temperature method, the external action is selected from the list comprising a thermal treatment and an ultraviolet irradiation. In another embodiment of the disclosed method, the thermal treatment is carried out at a temperature not exceeding the fusion temperature of the substrate material.

A more complete assessment of the present invention and its advantages will be readily achieved as the same becomes better understood by reference to the following detailed description, considered in connection with the accompanying drawings and detailed specification, all of which forms a part of the disclosure. Embodiments of the invention are illustrated, by way of example only, in the following Figures, of which:

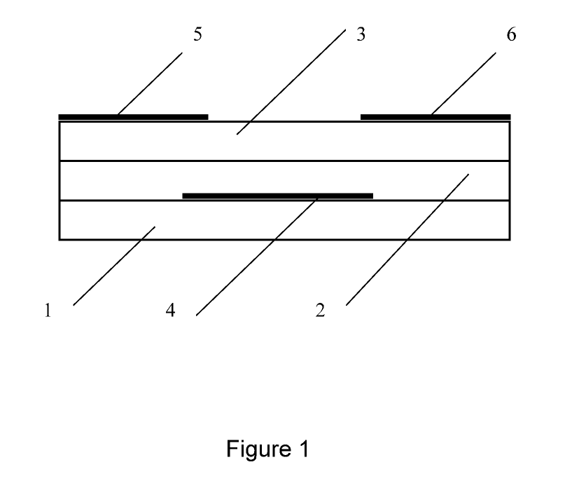

FIG. 1 shows the cross section of the first possible configuration of a TFT according to the present invention (top-contact configuration).

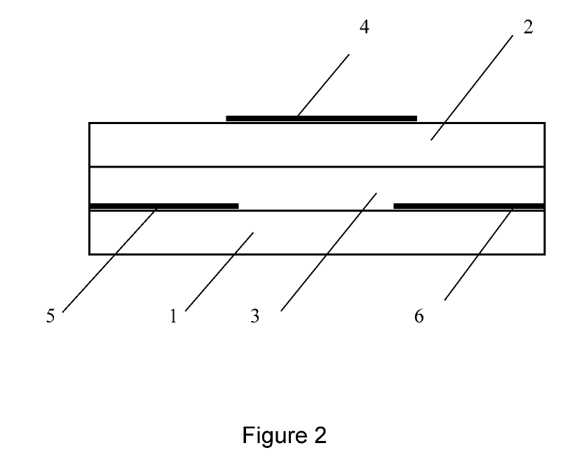

FIG. 2 shows the cross section of the second possible configuration of a TFT according to the present invention (bottom-contact configuration).

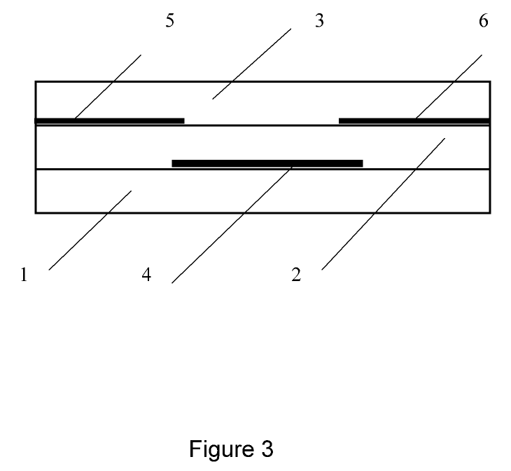

FIG. 3 shows the cross section of the third possible configuration of a TFT according to the present invention (bottom-contact configuration).

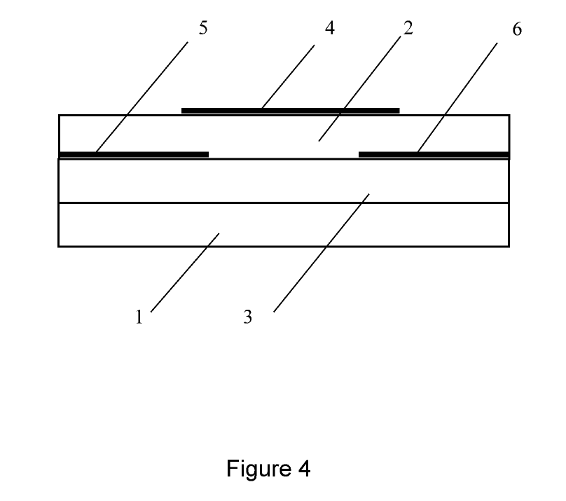

FIG. 4 shows the cross section of the fourth possible configuration of a TFT according to the present invention (top-contact configuration).

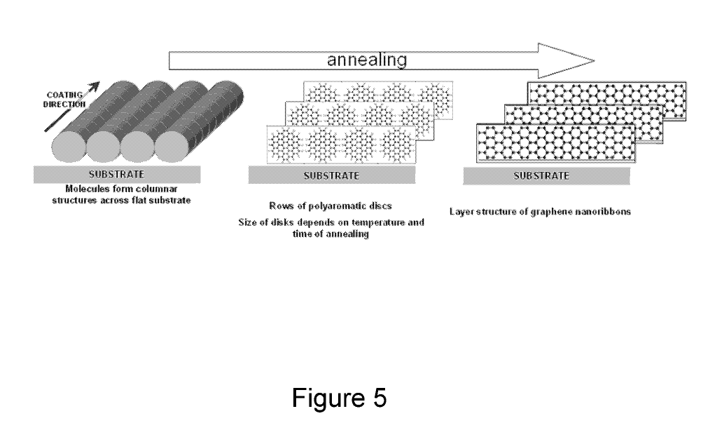

FIG. 5 shows the scheme of material structure transformations during annealing in the case of planar supramolecular orientation.

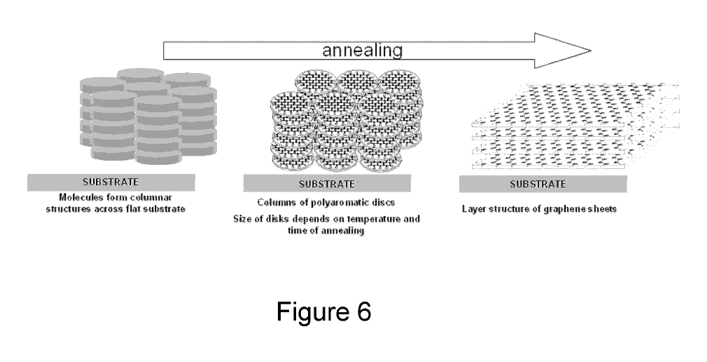

FIG. 6 shows the scheme of material structure transformations during annealing in the case of homeotropic supramolecular orientation.

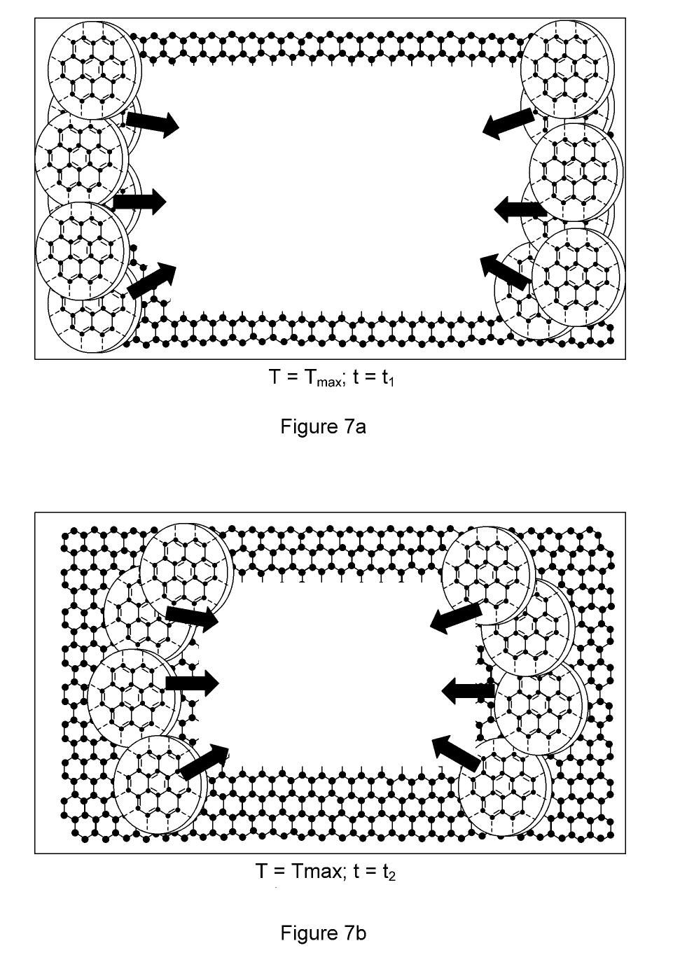

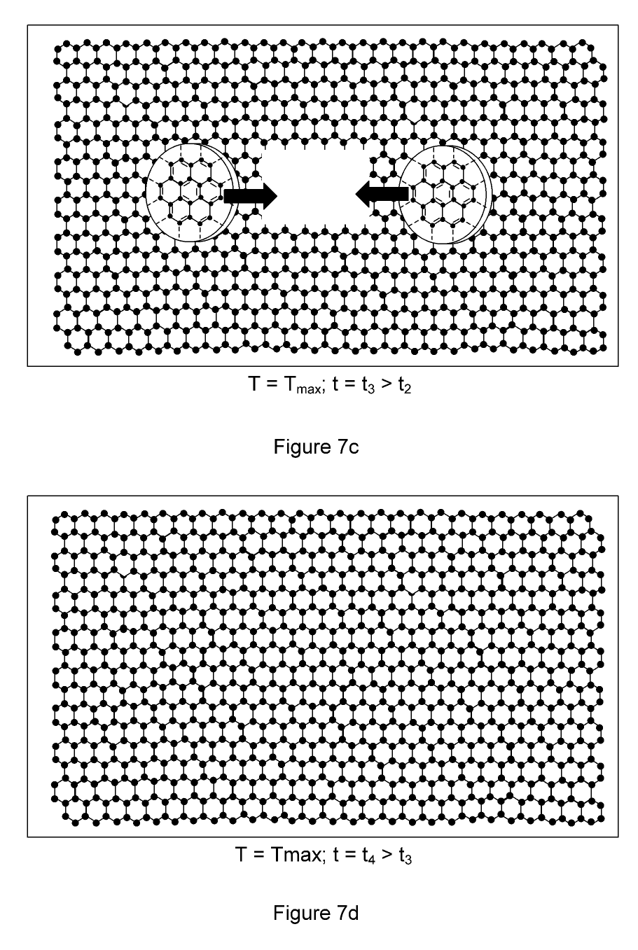

FIGS. 7a-7d schematically show as holes in the carbon-based layer are overgrown with the carbon-conjugated residues in the case of graphene-like sheets orientation parallel to surface of the carbon-based layer.

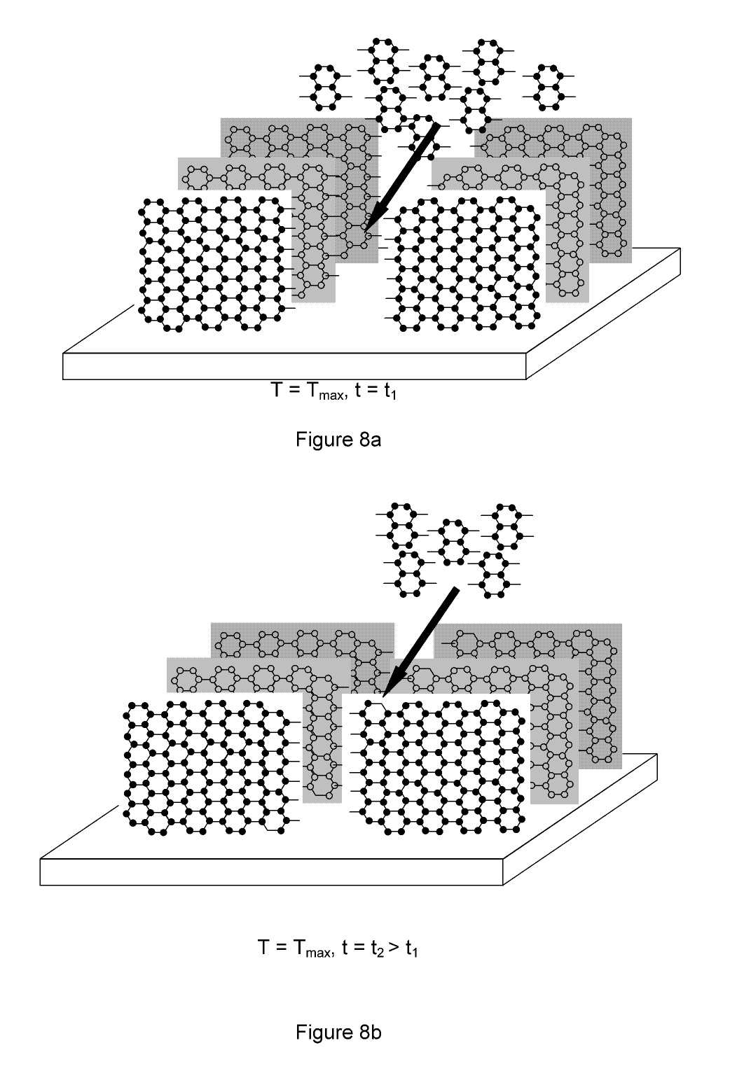

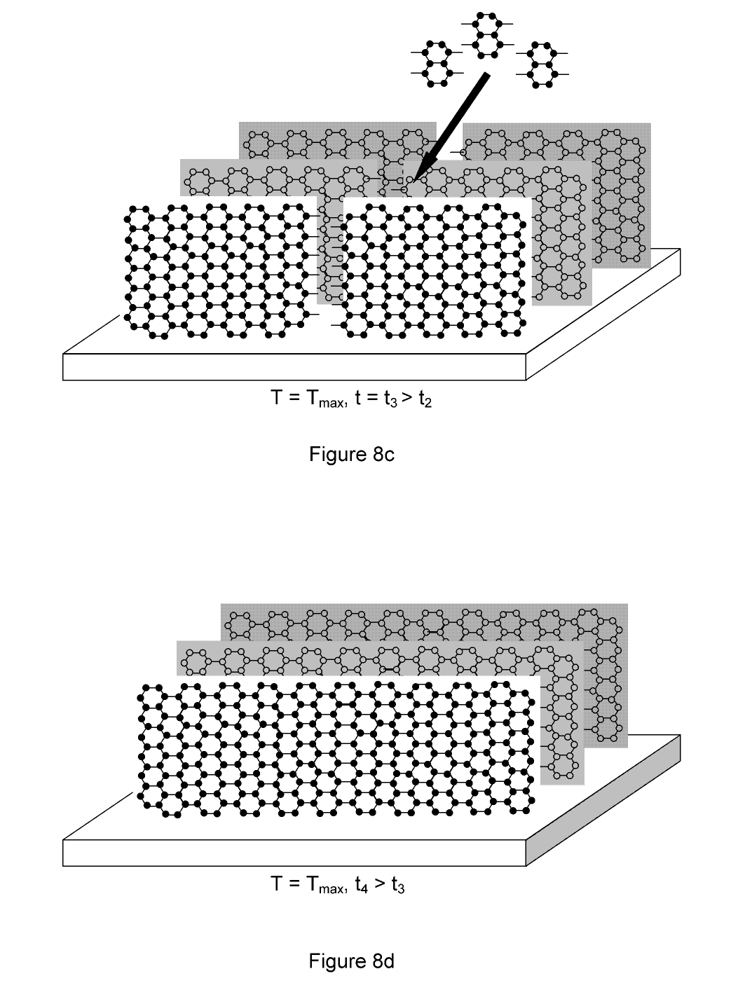

FIGS. 8a-8d schematically show as holes in the carbon-based layer are overgrown with the carbon-conjugated residues in the case of graphene-like nanoribbons orientation perpendicular to surface of the carbon-based layer.

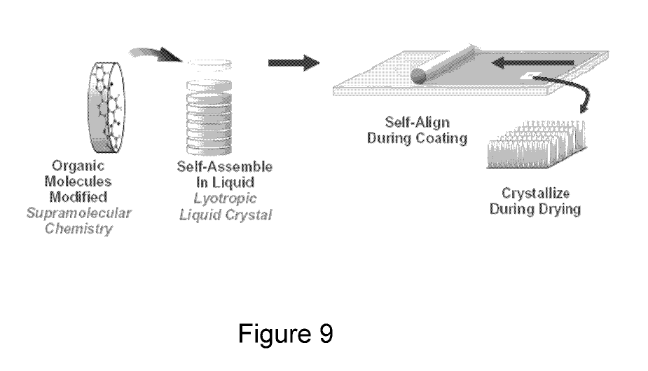

FIG. 9 shows the scheme of Cascade Crystallization technique.

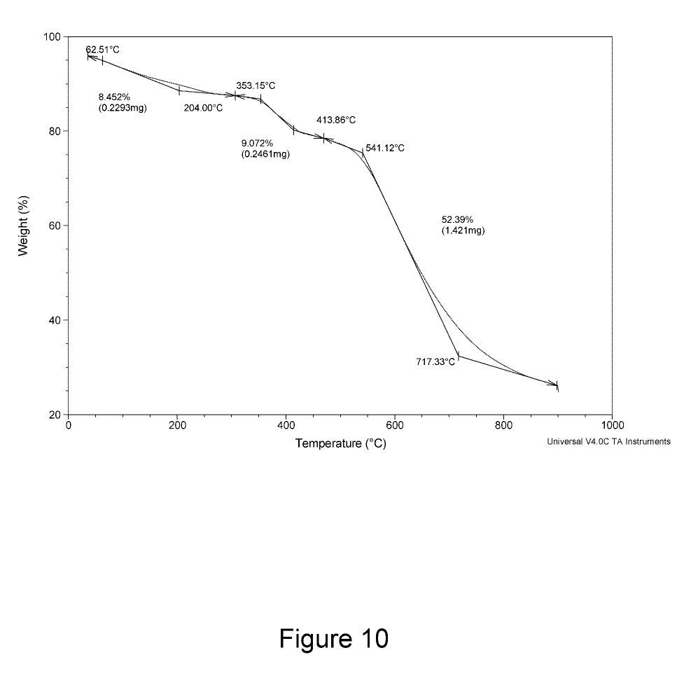

FIG. 10 shows the TG curve of bis-carboxy DBIPTCA.

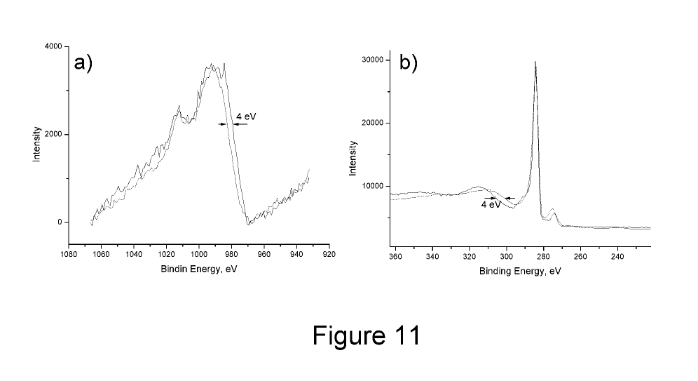

FIG. 11 shows the comparison of the CKLL (a) and C1s (b) lines of bis-carboxy DBIPTCA annealed at 650° C. during 30 minutes (red line) and graphite (black line).

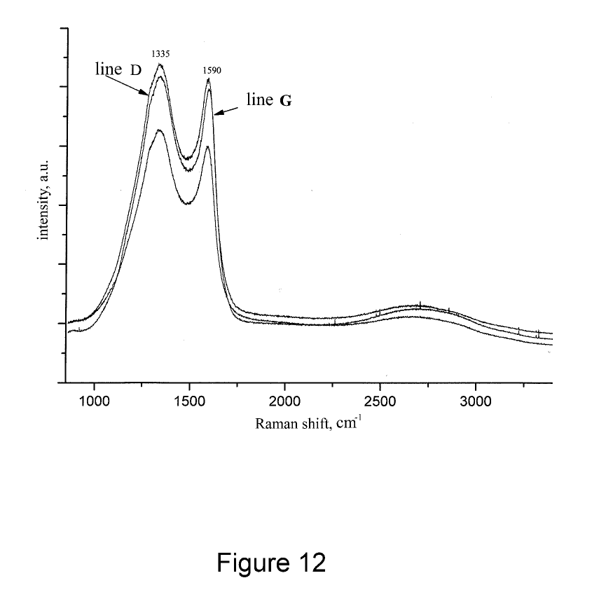

FIG. 12 shows the Raman spectra of carbon-based layer. Curves were obtained in different points of the layer.

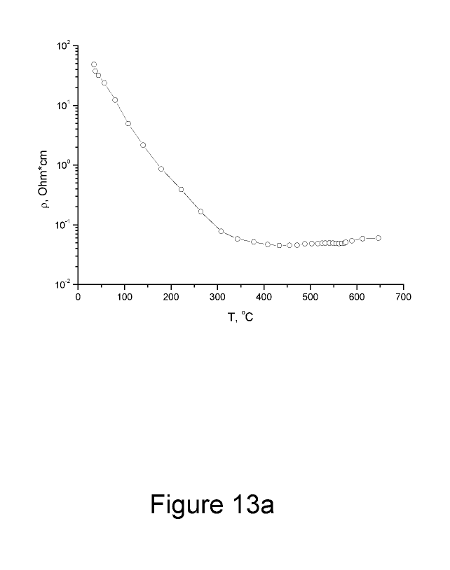

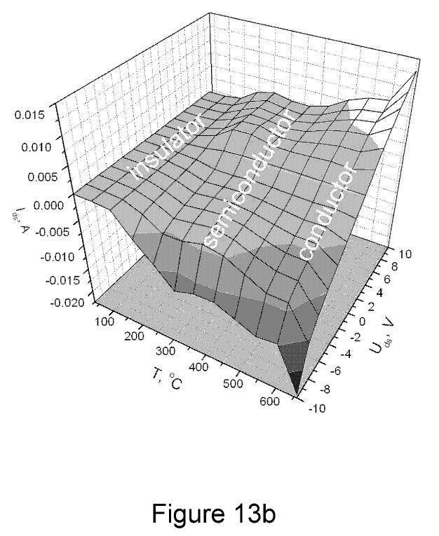

FIGS. 13a-13b show the in-situ resistivity measurements of bis-carboxy DBIPTCA film during annealing in vacuum.

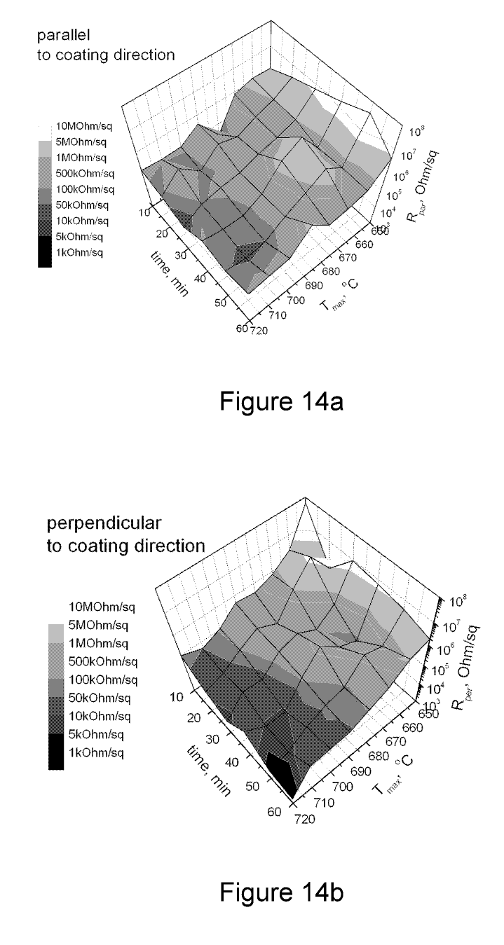

FIG. 14a-14b shows the sheet resistance of the carbon-based layer obtained at different annealing times and temperatures. The resistance was measured parallel (par) and perpendicular (per) to coating direction.

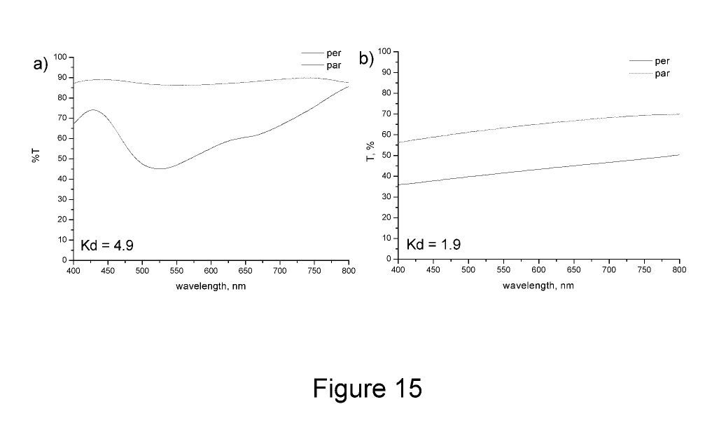

FIG. 15 shows the transmittance spectra of bis-carboxy DBIPTCA films a) initial and b) annealed at 700° C. during 10 minutes.

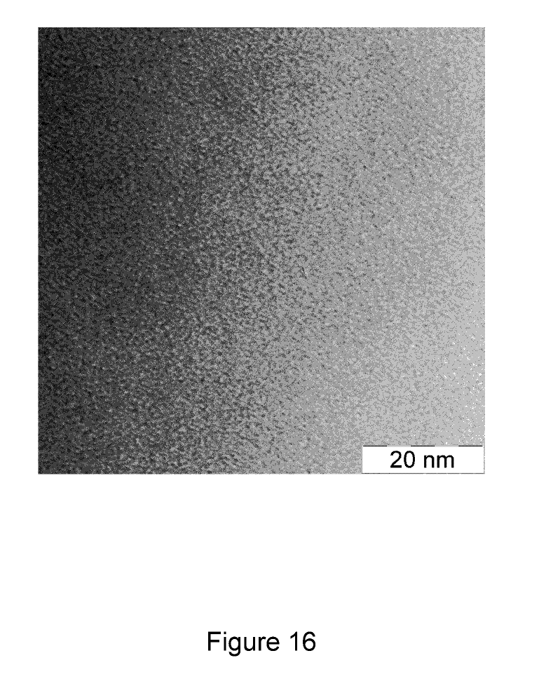

FIG. 16 shows the TEM image of bis-carboxy DBIPTCA film annealed at 650° C. during 30 minutes.

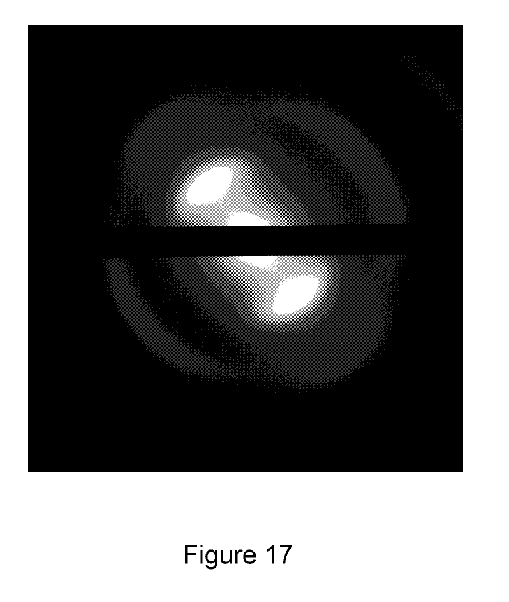

FIG. 17 shows the electron diffraction on bis-carboxy DBIPTCA film annealed at 650° C. during 30 minutes.

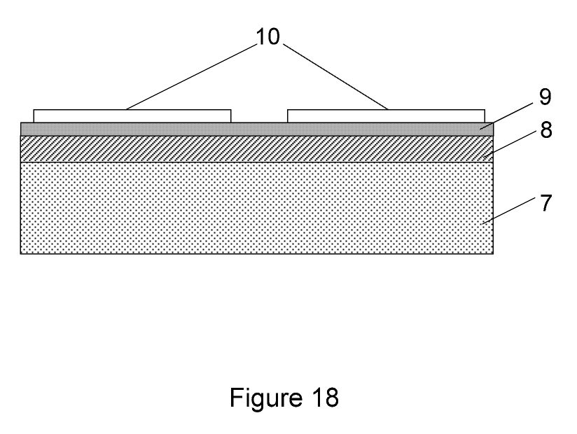

FIG. 18 shows the structure of the thin film transistor according to the present invention.

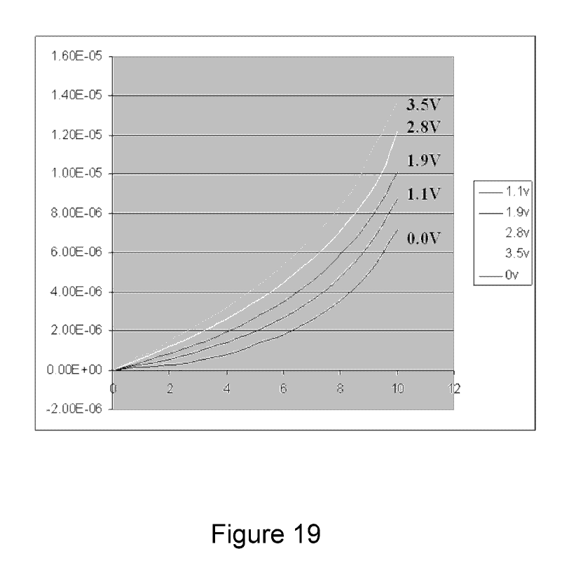

FIG. 19 shows measured current-voltage characteristics of disclosed TFT.

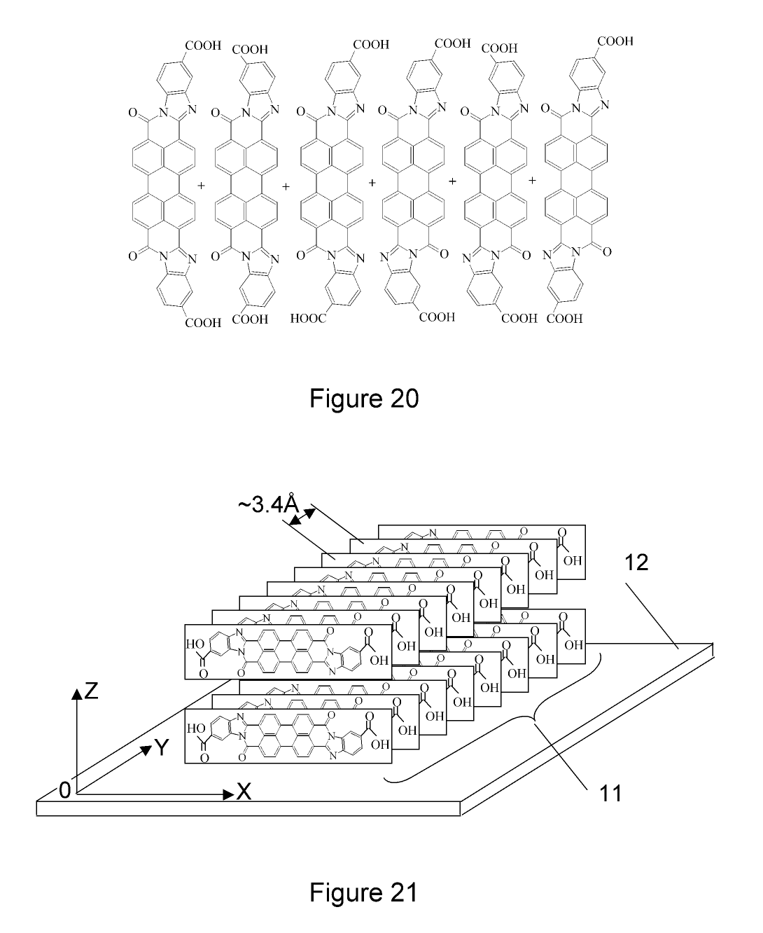

FIG. 20 shows chemical formulas of six isomers of Bis(carboxybenzimidazoles) of Perylenetetracarboxylic acids.

FIG. 21 shows a result of the drying step.

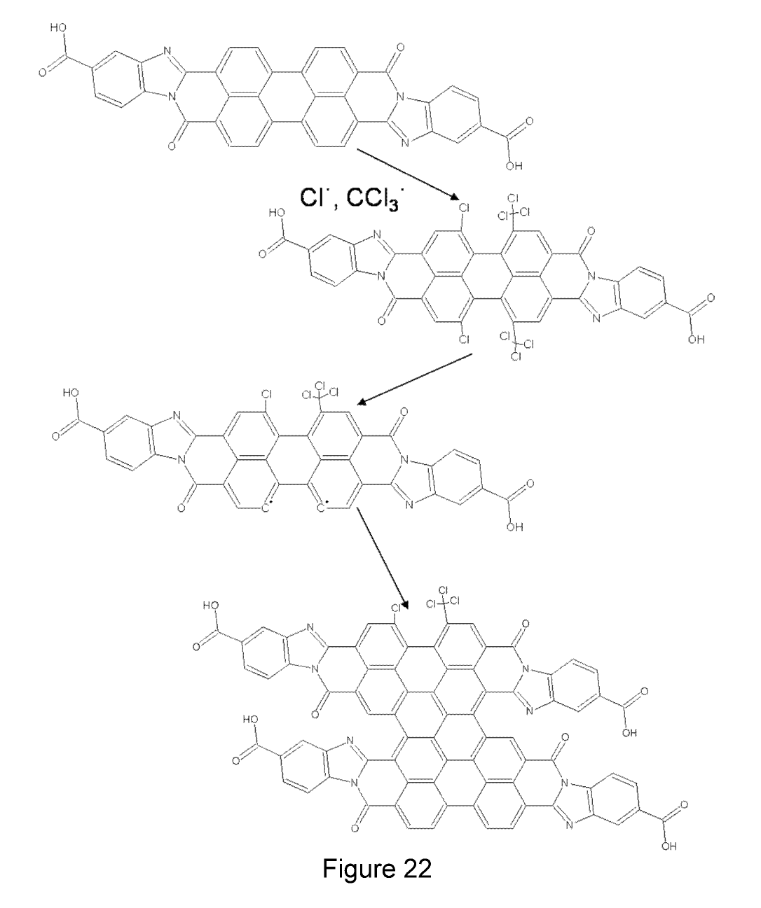

FIG. 22 schematically shows the process of low-temperature carbonization according to the present invention.

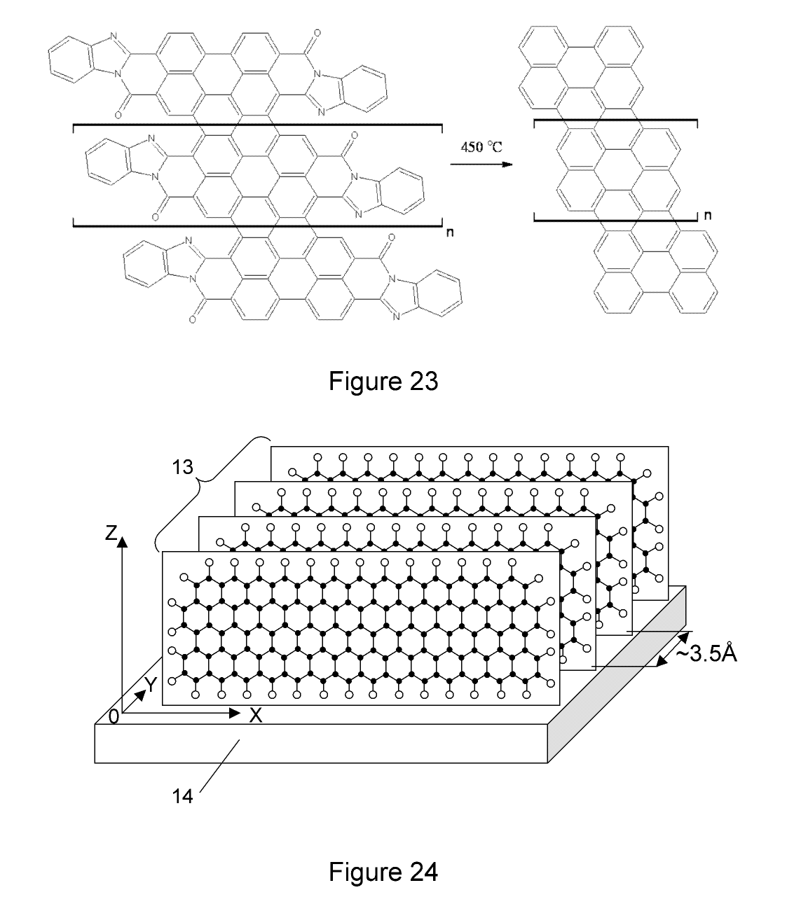

FIG. 23 schematically shows a pyrolysis process of the product of radical induced polymerization and formation of graphene-like carbon-based structure.

FIG. 24 shows the anisotropic graphene-like carbon-based layer on the substrate after the low-temperature carbonization step.

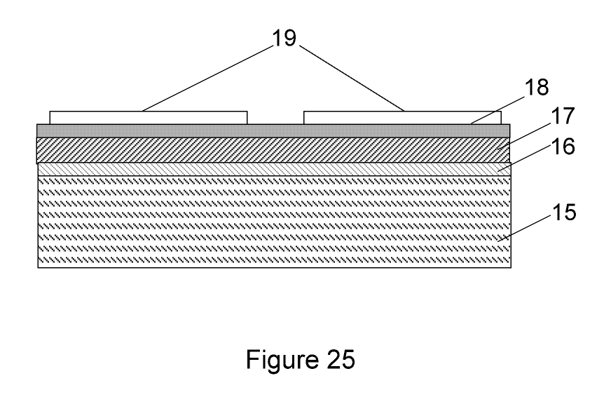

FIG. 25 schematically shows the thin film transistor according to the present invention.

FIG. 1 schematically shows a thin film transistor, wherein the electrically conductive gate electrodes (4) are located on the substrate (1); the insulator layer (2) is located on said electrically conductive gate electrodes; the carbon-based layer (3) is located on said insulator layer (2) substantially overlapping with said gate electrodes; and the system of electrically conductive source (5) and drain (6) electrodes is located on said carbon-based layer.

FIG. 2 schematically shows a thin film transistor, wherein the system of electrically conductive source (5) and drain (6) electrodes is located on the substrate (1); the layer (3) is located on said source electrodes, drain electrodes and substrate; the insulator layer (2) is located on said carbon-based layer; and the electrically conductive gate electrodes (4) are located on said insulator layer.

FIG. 3 schematically shows a thin film transistor, wherein the electrically conductive gate electrodes (4) are located on the substrate (1); the insulator layer (2) is located on said electrically conductive gate electrodes; the system of electrically conductive source (5) and drain (6) electrodes is located on said insulator layer; and the carbon-based layer (3) is located on said source electrodes, drain electrodes, insulator layer substantially overlapping with said gate electrodes.

FIG. 4 schematically shows a thin film transistor, wherein the carbon-based layer (3) is located on the substrate (1); the system of electrically conductive source (5) and drain (5) electrodes is located on said carbon-based layer; the insulator layer (2) is located on said source electrodes, drain electrodes and carbon-based layer; and the electrically conductive gate electrodes (4) are located on said insulator layer.

In order that the invention may be more readily understood, reference is made to the following examples, which are intended to be illustrative of the invention, but are not intended to be limiting in scope.

### EXAMPLE 1

This example describes a method of producing a carbon-based layer according to the present invention. This method allows for formation of the carbon-based layer, comprising predominantly planar graphene-like structures. In other words the example represents the disclosed method of carbon-based layer production in large amount over wide surfaces (several squire meters or even larger). It allows wide using and low-cost manufacturing of the carbon-based layers for different electronic devises such as back TFT panels in LCD and integrated circuits. The method of carbon-based layer production is based on partial pyrolysis of the organic compound and thermally induced fusion of carbon aromatic compounds. The fusion reaction is well known as common reaction in production process of various synthetic products such as molded graphite from petroleum coke and coal-tar, pyrolytic graphite from methane and other gaseous hydrocarbons, vitreous carbon and fibers from polymers, carbon black from natural gas, charcoal from wood, coal from plants, etc. These organic precursors must be carbonized and, more often than not, graphitized, in order to form carbon and graphite materials.

All materials obtained in the same way have strongly disordered structure. Thus the listed materials do not have any remarkable electrical properties. To achieve formation of large continuous planar graphene-like structures by pyrolysis and fusion of polyaromatic cores it is necessary to use a precursor layer with ordered molecular structure. Thus control over the precursor layer allows formation of materials comprising continuous planar graphene-like structures and hence to achieve high electron mobilities. By controlling the orientation of these graphene-like structure planes (planar (edge-on) or homeotropic (face-on)), the electrical, mechanical, and thermal properties of the resulted carbon-based layer can be tailored.

Graphene-like carbon-based nanoribbons disposed perpendicularly to substrate surface are formed in a fusion process in the case of planar orientation of supramolecules in discotic LC films as it is shown in FIG. 5. It was shown that electrical properties of graphene-like nanoribbons directly depend on the width of the nanoribbons (see, Zhihong Chen, Yu-Ming Lin, Michael J. Rooks and Phaedon Avouris, “Graphene Nano-Ribbon Electronics”, Condensed Matter 0701599 (2007); Melinda Y. Han, Barbaros Özyilmaz, Yuanbo Zhang, Philip Kim, “Energy Band-Gap Engineering of Graphene Nanoribbons”, Physical Review Letters 98, 206805 (2007)). Formation of graphene-like nanoribbons from planar aligned discotic LC by fusion reaction allows precise controlling of nanoribbons width simply by controlling of initial liquid layer thickness.

In the case of homeotropic orientation of discotic LC the carbon-based layers with planar graphene-like sheets oriented predominantly parallel to substrate surface are formed during fusion process shown in FIG. 6. In this case the thickness of initial liquid layer defines the amount of graphene-like sheets in the carbon-based layer. The liquid layer thickness depends only on solution concentration and coating parameters for layers obtained from LLC solution.

The conductivity of carbon-based layer is continuously changed during the annealing process. There are three states of the electrical conductance which have fundamental distinctive features.

First, in its initial state the carbon-based layer consists of organic molecules and has insulating properties. The carbon-based layer remains in this state until complete pyrolysis.

In the second state, there are carbon residues on substrate surface after completion of pyrolysis. The carbon residues comprise poly-aromatic cores which are ordered parallel to each other. The poly-aromatic cores fuse together and form planar graphene-like structures which are also ordered on the substrate. In this state, the carbon-based layer has semiconductor-like resistivity (˜1-10⁻³ Ohm*cm). Resistivity decreases with increasing sizes of the graphene-like structures and decreasing gaps between the graphene-like structures. One possible mechanisms of electrical conductance in this case is hopping conductivity.

In the third state, a further fusion of all graphene-like structures leads to formation of continuous graphene-like nanoribbons or graphene-like sheets in the carbon-based layer structure, possibly with a few gaps between the graphene-like structures. The main type of structural defects in the carbon-based layer is point defects in hexagonal carbon lattice and deviation of graphene-like nanoribbons or graphene-like sheets from planer shape. The carbon-based layer has low resistivity along nanoribbons or sheets. The resistivity gradually decreases during the process of fusion and becomes comparable with metals (˜10⁻⁵-10⁻⁷ Ohm*cm). At high annealing temperature (more than 1300° C.) it is possible to obtain defect-free material with ballistic transport of charge carriers.

The fusion process provides uniformity of ordering of the carbon-based layers structure because of intensive diffusion processes in the reactor during high temperature annealing. At a high vacuum, the substance (predominantly carbon atoms) partially sublimates from the layer surface. Because of high temperature, there is strong diffusion process above layer surface. Sublimated carbon-conjugated residues enter into holes in the layer and immediately contact with free radicals which arose due to pyrolysis. Hence a hole (or crack) is overgrowth gradually. The holes in the carbon-based layer are overgrown with the carbon-conjugated residues in the case of graphene-like sheets orientated parallel to surface of the carbon-based layer as schematically shown in the FIGS. 7a-7d and in the case of graphene-like nanoribbons orientated perpendicular to surface of the carbon-based layer as schematically shown in the FIGS. 8a-8d.

The limiting stage of the described process is diffusion of carbon-conjugated residues towards a defect in the carbon-based layer. The kinetics of the diffusion processes depend only on processing temperature and time. It is possible to achieve uniform carbon-based layer with ideal structure in the case of relatively fusion process.

It is important to note that overgrowing of layer defects does not damage the parallel orientation of the graphene-like sheets and graphene-like nanoribbons in the carbon-based layer because orientation in graphene-like sheets and graphene-like nanoribbons alignment presets the direction of the overgrowing process. Thus, continuous planar graphene-like sheets and graphene-like nanoribbons are formed during fusion in vacuum, which causes high mobility of charge carriers and hence high conductivity is possible. Also it allows formation of large areas of thin (several nanometers) and uniform carbon-based layers.

To obtain precursor layers with ordered structure, a Cascade Crystallization technology is used. The Cascade Crystallization process involves a chemical modification step and four steps of ordering during the precursor layer formation [see, Igor V. Khavrounyak, Pavel I. Lazarev, Konstantin P. Lovetski, Mikhail V. Paukshto, U.S. Patent 20050146671 (2005)]. The chemical modification step introduces hydrophilic groups on the periphery of the molecule in order to impart amphiphilic properties to the molecule. Amphiphilic molecules stack together into supramolecules, which is the first step of ordering. By choosing specific concentration, supramolecules are converted into a liquid-crystalline state to form a lyotropic liquid crystal, which is the second step of ordering. The lyotropic liquid crystal is deposited under the action of a shear force (or meniscus force) onto a substrate, so that the shear force (or the meniscus) direction determines the crystal axis direction in the resulting solid precursor layer. This shear-force assisted directional deposition is the third step of ordering, representing the global ordering of the crystalline or polycrystalline structure on the substrate surface. The final (fourth) step of the Cascade Crystallization process is drying/crystallization, which converts the lyotropic liquid crystal into a solid precursor layer. The scheme of actions described above is shown in FIG. 9.

The precursor layer produced by the Cascade Crystallization process has a global order. That means that the direction of the crystallographic axis of the precursor layer over the entire substrate surface is controlled by the deposition process (by the orientation of supramolecules), with limited influence of the substrate surface. Molecules of the deposited material are packed into lateral supramolecules with limited freedom of diffusion or motion. The precursor layer is characterized by an inter-planar spacing of 3.4±0.3 (depending on the molecular structure of the precursor).

Annealing of the ordered precursor layer leads to pyrolysis of organic molecules. Commonly, carbonization is performed in a reducing or inert environment with slowly heating, over a range of temperature that varies with the nature of the particular precursor and may extend to 1300° C. The organic material is decomposed into a carbon residue and volatile compounds diffuse out to the atmosphere. The process is complex and several reactions may take place at the same time such as dehydrogenation, condensation and isomerization.

The diffusion of the volatile compounds to the atmosphere is a critical step and must occur slowly to avoid disruption and rupture of the carbon network. As a result, carbonization is usually a slow process. Its duration may vary considerably, depending on the composition of the end-product, the type of precursor, the thickness of the material, and other factors.

Bis(carboxybenzimidazoles) of perylene tetracarboxylic acid (bis-carboxy DBIPTCA) was used as a precursor organic compound. The organic compound has amphiphilic nature due to polyaromatic core and carboxylic groups on there ages. The amphiphilic nature results in supramolecules formation in polar solvents (e.g. water). The water solution with concentration 2.5 wt % of bis-carboxy DBIPTCA was used because the concentration ensures lyotropic liquid crystalline phase formation and low viscosity of the solution. Hence, coating of thin layers (less than 10 nm) with ordered supramolecular structure is available. The ammonia solution was added to the mixture to ensure better solubility of the organic compound. A surfactant (Surfynol 465, 1%) was added to the solution. The addition of the surfactant assured good interaction between the result solution and the substrate surface. Concentration of surfynol in final solution was 0.05 wt %.

The precursor layers were coated according to the Cascade Crystallization process. The Cascade Crystallization process was carried out on coating machine Erichsen 509MCIII. Changing of coating parameters (coating velocity, temperature and humidity of environment, etc.) allows formation of solid precursor layers with the required thickness in the range from few nanometers to several microns. The optimal composition of precursor solution and coating parameters allowed formation of films with highly uniform thickness (±5 nm or better) and highly-ordered supramolecular structure.

The solid precursor layer was annealed in vacuum furnace. The vacuum level was about 10⁻³ torr. The layer was heated to a temperature in the range of 650-720° C. with heating ramped at a rate of about 5°/min. Exposure time was changed from 10 minutes to approximately 1 hour at these temperatures.

The transmittance of the carbon-based layers was measured with two light polarizations: parallel and perpendicular to coating direction of organic precursor. Measurements were carried out using UV/Vis/NIR spectrophotometer Varian Cary 500 Scan in wavelength interval 400-800 nm. A dichroic ratio (Kd) of the films was calculated using the optical transmittance data. The K_{d} is defined as the ratio of optical densities:

$${K}_{d} = \begin{matrix}{D}_{per} \\ {D}_{par}\end{matrix} = \begin{matrix}log ( {T}_{per} ) \\ log ( {T}_{par} )\end{matrix} ,$$

there Tₚₐᵣ (Tₚₑᵣ) is transmittance with light polarization parallel (perpendicular) to coating direction.

Raman spectra were recorded in the spectral region 800-3500 cm⁻¹ using Raman spectrometer LabRAM Jobin Yvon equipped with microscopes, TV camera and cooled CCD detector. The exciting radiation was 632.8 nm line of He—Ne laser. The power of the laser radiation did not exceed 1 mW. Scattered light was collected according to reflection scheme)(180°. The spectral width of the slit was 2 cm⁻¹.

Spectra were registered using the spectrometer XSAM800 (Kratos, Great Britain). As the excitation source, the Mg anode with the discriminatory radiation energy MgK_{α}=1253.6 eV was used. Power excited on the anode during the spectra registration was lower than 90 W. Measurements were conducted in vacuum ˜5·10⁻¹⁰ torr. PE spectra were registered with a step of 0.1 eV. The spectrometer energy scale was standardized by standard methodic using the following bond energies: Cu 2p_{3/2}−932.7 eV, Ag 3d_{5/2}−368.3 eV and Auf_{7/2}−84.0 eV.

Surface charging was considered traditionally on the state C—C/C—H, which has energy accepted as 285.0 eV. Quantitative analysis was performed according to the element sensibility coefficients. TGA curves were registered using the simultaneous DSC-TGA SDT-Q600. TG analysis was performed in nitrogen flow with heating rate 5 deg/min. TEM was performed on a transmittance electron microscope LEO912 AB OMEGA. The hardness of the annealed layers was measured by the pencil test on Erichsen Scratch Hardness Tester 291.

The TG curve (see, FIG. 10) obtained in nitrogen flow with heating rate 5 deg/min indicates that there are three main stages during annealing of bis-carboxy DBIPTCA film: 1) water and ammonia removing from the layer (24-300° C.); 2) Decarboxylation process (300-540° C.), and 3) Removing of benzimidazoles from the layer (from about 540° C.).

The annealed bis-carboxy DBIPTCA layers consist mostly of carbon atoms. According to XPES, the annealed layers consist of approximately 83% carbon, with the remainder consisting mostly of N and O. Control over the atomic composition of the material is possible by changing the annealing parameters (e.g. annealing time and temperature, ambient gases). Moreover, the carbon lines in the photoelectron spectra are shifted by about 4 eV relative to the lines for graphite (see FIG. 11). This indicates the presence of graphene-like 2D structures in the carbon-based layers and means that there is no significant electron interaction between planar graphene-like sheets and graphene-like nanoribbons.

The results of Raman scattering on annealed bis-carboxy DBIPTCA layers proved that all carbon in the layers is sp²-hybrided. There are two lines (D and G) typical for sp² carbon in the Raman spectra (see, FIG. 12). The resulted spectra of Raman scattering allowed calculation of crystalline size L in our carbon-based layers using the Knight formula L=C(λ)(I_{D}/I_{G}), where C(λ) is a fitting parameter which takes into account the wavelength of laser used to probe the samples, I_{G} is the intensity of the G lines, I_{D} is the intensity of the D line. Matthews M. J. and coworkers showed that the function C(λ) has linear character, namely C(λ)≈C₀+λC₁, where C₀=−126 Å, C₁=0.033 in wavelength interval 400-700 nm [see, M. J. Matthews, M. A. Pimenta, G. Dresselhaus, M. S. Dresselhaus, M. Endo, “Origin of dispersive effects of the Raman D band in carbon materials” Physical Review B 59 (10), pp. R6585-R6588 (1999)]. The calculated crystalline size by the Knight formula from Raman spectra (see FIG. 12) is about 4.5 nm.

The formed carbon-based layers have average thickness about 30 nm in all annealing experiments. The hardness of the initial solid precursor layers and the carbon-based layers after annealing was measured by the pencil test, which is commonly used for testing coatings hardness. The hardness is B in the case of precursor layers and 8H in the case of annealed carbon-based layers. The increasing hardness during annealing provides evidence about the hardening of the layers' atomic structure due to the carbonization and fusion processes. It is important to note that a harder atomic lattice allows better conductivity of a material.

Indeed, annealing leads to a significant increase in the conductance of the carbon-based layers. The in-situ measurement of conductance of the bis-carboxy DBIPTCA layer during annealing shows that annealing leads to a considerable reduction of the resistivity of the layer (see FIGS. 13a and 13b). Some increase in resistivity at temperatures higher than 500° C. is caused by resistance temperature dependence. This means that the material has a metallic nature at high temperatures. Also the resistivities of annealed films are near metallic resistivities.

Results of the resistivity measurements are shown in FIG. 14. The decreasing sheet resistance with increasing annealing time and temperature provides evidence for the presence of the fusion process during annealing. The graphene-like nanoribbons are formed during the fusion. The length of the graphene-like nanoribbons depends on the temperature and time of annealing. There are longer graphene-like nanoribbons in the carbon-based layers annealed at higher temperatures for longer durations. The carbon-based layers with longer graphene-like nanoribbons have lower resistance.

Conductance in annealed bis-carboxy DBIPTCA layers is anisotropic. The layers have higher resistivity perpendicular to the coating direction and lower resistivity parallel to the coating direction (see, FIG. 14). The average ratio Rₚₐᵣ/Rₚₑᵣ (where Rₚₐᵣ (Rₚₑᵣ) is the resistivity measured parallel (perpendicular) to coating direction) varies from 2 to 8 as the annealing parameters are varied. This fact also proves the presence of structural anisotropy in the carbon-based layers.

It would seem that the growth of graphene-like nanoribbons leads to decreasing resistance perpendicular to the coating direction only (in the plane of the ribbons) and does not influence the conductivity properties parallel to coating direction (perpendicular to ribbons plane). Nevertheless, some reduction of the resistivity of the carbon-based layers in the direction parallel to the coating direction was observed with increasing annealing time and temperature (see FIG. 14). The cause of this change was disordering of the carbon-based layer molecular structure during the annealing process. Rotation and drifting of carbon conjugated residues may lead to fusion reaction between neighboring graphene-like nanoribbons. Also imperfections of molecular order in initial precursor layers cause the intergrowth of neighboring graphene-like nanoribbons during annealing. The contacts between graphene-like nanoribbons lead to decreasing resistivity parallel to the coating direction. The number of the contacts increases with increasing fusion temperature and time. Thus, the reduction of resistivity parallel to the coating direction was obtained. Because of the predominant orientation of molecules in the layers, the fusion reaction takes place mostly between the graphene-like structures in the layer. Thus, the rate of the decrease is less than the rate of decrease of resistivity measured perpendicular to the coating direction. Resistivity decreases about 3·10⁴ times in the case of measurements perpendicular to coating direction and about 10³ times in the case of measurements parallel to coating direction.

The character of the transmittance curves was strongly changed after annealing. Transmittance of annealed carbon-based layers is close to linear (see FIG. 15b) in contrast to transmittance of initial precursor layers (see FIG. 15a). The linear character of transmittance indicates that there are no side groups in the molecular structure of the annealed layers and that there are large graphene-like nanoribbons.

The differences in transmittance spectra with light polarizations perpendicular and parallel to coating direction prove that there is preferential orientation of molecules in carbon nanoribbons layer after annealing. Moreover, the orientation of molecular agglomerates in the final carbon-based layers has its direction similar to the direction of orientation of the molecules in the initial precursor layers. However, the carbon-based layers after annealing have lower dichroic ratio (Kd) than the initial precursor layers. The value of the dichroic ratio is directly correlated with molecular ordering in the initial precursor layer. The molecular structure of the layers disorders during annealing. This may be due to intensive thermal vibration of molecules at high temperatures.

Direct structural observation of annealed carbon-based layers such as transmittance electron microscopy (TEM) confirms the presence of ordered graphene-like nanoribbons in the material structure (see FIG. 16). The presence of the orientation is proved also by electron diffraction images (see FIG. 17). There are two clear maxima, which correspond to 1D ordering in the films. The reflexes on the electronograms relate to the following average spaces: 3.54 Å, 2.12 Å, 1.75 Å and 1.19 Å. The 3.54 Å is the space between planar graphene-like nanoribbons. According to electron diffraction, this space has periodicity in one direction only that is correlated with an order of planar graphene-like nanoribbons. Other spaces are related to diffraction on atomic planes in the hexagonal lattice of planar graphene-like nanoribbons.

### EXAMPLE 2

This example describes the disclosed thin film transistor based on anisotropic thin carbon-based layer and measurements of charge carriers' mobility in the annealed bis-carboxy DBIPTCA layer prepared according to the method described in Example 1. For this purpose the thin film transistor with an oxide layer based on annealed bis(carboxybenzimidazoles) of prerylenetetracarboxylic acid (bis-carboxy DBIPTCA) was made. The structure of the thin film transistor is shown in FIG. 18. The thin film transistor structure comprises the following elements: n-doped silicon wafer that serves as a gate electrode (7), SiO₂ layer as a gate insulator (8), bis-carboxy DBIPTCA active carbon-based layer (9), golden source and drain contacts (10). The n-type silicon wafer (7) serves as a substrate. The channel size was 80 μm×2.5 mm. The thickness of the gate insulator is about 1.48 μm.

Coating of bis-carboxy DBIPTCA on silicon wafer above oxide layer was carried out using a Mayer rod. Thickness of the bis-carboxy DBI PTCA layer was 58 nm. Annealing of bis-carboxy DBIPTCA was performed at 650° C. during 40 minutes in vacuum. The golden contacts (10) were disposed by thermal evaporation technique on top of the active layer. The measured current-voltage characteristics for TFT are shown in FIG. 19.

Calculations of the mobility were made on the basis of a commonly used technique. A linear region of device operation, V_{DS}|<V_{GS}−V_{T}| where V_{T} is the threshold voltage, V_{GS} is the gate-source voltage, and V_{DS} is the drain-source voltage was used. In this region mobility is given by

$$μ = \begin{matrix}L & 1 & 1 & \partial {I}_{D} \\ W & C & {V}_{DS} & \partial {V}_{GS}\end{matrix} ,$$

where C is the gate insulator capacitance per unit area, I_{D} is the drain-source current, L and W are the transistor channel length and width respectively. The calculated mobility is equal to 0.073 cm²/v·sec.

### EXAMPLE 3

This example describes a low-temperature method of producing a carbon-based layer according to the present invention. The metallic carbon-based layer comprising graphene-like carbon-based structures was formed by a mixture of bis(carboxybenzimidazoles) of prerylenetetracarboxylic acids (bis-carboxy DBIPTCA). As a first step, a water solution of bis-carboxy DBIPTCA is applied on a substrate. The solution comprises a mixture of six isomers as shown in FIG. 20, which predominantly planar carbon-conjugated cores are shown in Table 1, structures 4 and 5. Bis-carboxy DBIPTCA is a π-conjugated organic compound, where the predominantly planar carbon-conjugated core (CC in formula I) comprises rylene fragments, the benzimidazole groups serve as hetero-atomic groups, and carboxylic groups serve as substituents providing solubility. In addition to that, the carboxylic groups provide for the formation of rod-like molecular stacks. In this Example glass is used as a substrate material. The Mayer rod technique is used to coat the water-based solution of bis-carboxy DBIPTCA. During the second step drying is performed. By the end of the drying step, the layer usually retains about 10% of the solvent. As a result of the drying step the layer comprises supramolecules oriented along the coating direction. FIG. 21 schematically shows the supramolecule (11) oriented along the y-axis and located on the substrate (12). The distance between the planes of bis-carboxy DBIPTCA is approximately equal to 3.4 A.

During the next step the solid layer is placed into a gas-phase environment containing molecules which are sources of free radicals or benzyne fragments. In this example carbon tetrachloride CCl₄ is used.

Finally an external action is applied upon the solid layer stimulating low-temperature carbonization of the graphene-like carbon-based structures. Heating is used as the external action. In this case, temperature induced free radical formation is realized. Generation of free radicals in the reaction sphere by decomposition of CCl₄ occurs through: CCl₄ [symbol] CCl₃.+Cl.. The reaction is temperature induced and takes place at 200° C. or not much higher. Free radical formation on a carbon aromatic core is described with following reaction: Ar+Cl. [symbol] ArCl.→Ar.+HCl, where Ar is a polyaromatic compound. Polyaromatic molecules with free radicals are easily fused together: Ar.+Ar.═Ar—Ar. This process is schematically shown in FIG. 22. FIG. 23 schematically shows pyrolysis process of the product of radical induced polymerization and formation of graphene-like carbon-based structure. FIG. 24 schematically shows the anisotropic graphene-like carbon-based layer (13) on the substrate (14) after the low-temperature carbonization step.

### EXAMPLE 4

This example describes the disclosed thin film transistor based on an anisotropic thin carbon-based layer made of a bis-carboxy DBIPTCA layer prepared according to the method described in Example 3. The structure of the thin film transistor is shown in FIG. 25. The thin film transistor structure comprises the following elements: a substrate made of glass (15), a metallic layer that serves as a gate electrode (16), an SiO₂ layer as a gate insulator (17), a bis-carboxy DBIPTCA active carbon-based layer (18), and golden source and drain contacts (19). The channel size is 80 μm×2.5 mm. The thickness of the gate insulator is about 1.48 μm.

The coating of bis-carboxy DBIPTCA on the silicon wafer above the oxide layer was carried out using a Mayer rod. The thickness of the bis-carboxy DBIPTCA layer was 58 nm. Low-temperature carbonization of bis-carboxy DBIPTCA was performed as described in Example 3. The golden contacts (19) were deposited by thermal evaporation on top of the active layer.

Although the present invention has been described in detail with reference to the preferred embodiments, persons possessing ordinary skill in the art to which this invention pertains will appreciate that various modifications and enhancements may be made without departing from the spirit and scope of the claims that follow.

1-119. (canceled)

120. A thin film transistor comprising:
a carbon-based layer,
a system of electrically conductive source and drain electrodes being in contact with the carbon-based layer, and
at least one electrically conductive gate electrode intended for control of an electric current between the source and the drain electrodes,
wherein said carbon-based layer is electrically conducting layer, has thickness in the range from approximately 1 to 1000 nm, and comprises predominantly planar graphene-like structures.

121. A thin film transistor according to claim 120, wherein the graphene-like structures have form of planar graphene-like nanoribbons which are predominantly continuous within the entire carbon-based layer, and the planes of said nanoribbons are oriented predominantly perpendicularly to the carbon-based layer surface.

122. A thin film transistor according to claim 120, wherein the graphene-like structures have form of planar graphene-like sheets which are predominantly continuous within the entire carbon-based layer, and the planes of said sheets are oriented predominantly parallel to the carbon-based layer surface.

123. A thin film transistor according to claim 120, further comprising a substrate.

124. A thin film transistor according to claim 120, further comprising an insulator layer located between the carbon-based layer and at least one electrically conductive gate electrode.

125. A thin film transistor according to claim 124, wherein at least one electrically conductive gate electrode is located on the substrate, the insulator layer is located on said electrically conductive gate electrode and is in contact with it, the carbon-based layer is located on said insulator layer substantially overlapping with said gate electrodes; and the system of electrically conductive source and drain electrodes is located on said carbon-based layer and is in contact with this layer.

126. A thin film transistor according to claim 124, wherein the system of electrically conductive source and drain electrodes is located on the substrate; the carbon-based layer is located on said source electrodes, drain electrodes and substrate and is in contact with them; the insulator layer is located on said carbon-based layer and is in contact with this layer; and the electrically conductive gate electrodes are located on said insulator layer and is in contact with this layer.

127. A thin film transistor according to claim 124, wherein the electrically conductive gate electrodes are located on the substrate; the insulator layer is located on said electrically conductive gate electrodes and is in contact with them; the system of electrically conductive source and drain electrodes is located on said insulator layer and is in contact with this layer; and the carbon-based layer is located on said source electrodes, drain electrodes and insulator layer substantially overlapping with the gate electrodes.

128. A thin film transistor according to claim 124, wherein the carbon-based layer is located on the substrate; the system of electrically conductive source and drain electrodes is located on said carbon-based layer and is in contact with this layer; the insulator layer is located on said source electrodes, drain electrodes and carbon-based layer and is in contact with them; and the electrically conductive gate electrodes are located on said insulator layer and is in contact with this layer.

129. A thin film transistor according to claim 120, further comprising an insulating passivation layer located on top of said transistor to protect the transistor from further processing exposures and from the ambient factors.

130. A thin film transistor according to claim 120, wherein the substrate is made of one or several materials of the group comprising Si, Ge, SiGe, GaAs, diamond, quartz, silicon carbide, indium arsenide, indium phosphide, silicon germanium carbide, gallium arsenic phosphide, gallium indium phosphide, plastics, glasses, ceramics, metal-ceramic composites, metals, and comprises doped regions, circuit features, multilevel interconnects, and the carbon-based layer, and wherein said plastic substrate is selected from the group comprising polycarbonate, Mylar, and polyimide.

131. A thin film transistor according to claim 121 wherein the width of the graphene-like nanoribbons provides the carbon-based layer with semiconductor properties due to the forming of an energy bandgap.

132. A thin film transistor according to claim 120, wherein the carbon-based layer possesses the n-type conductivity.

133. A thin film transistor according to claim 132, wherein the gate electrodes are made of a material of a high electron work function and selected from the group comprising nickel, gold, platinum, lead, ITO, and any combination thereof.

134. A thin film transistor according to claim 132, wherein the source and drain electrodes are made of a material of a low electron work function, and wherein the material of said gate electrodes is selected from the list comprising chromium, titanium, copper, aluminium, molybdenum, tungsten, indium, silver, calcium, and any combination thereof.

135. A thin film transistor according to claim 120, wherein the carbon-based layer possesses the p-type conductivity.

136. A thin film transistor according to claim 135, wherein the source and drain electrodes are made of a material of a low electron work function, and wherein the material of said source and drain electrodes is independently selected from the list comprising chromium, titanium, copper, aluminium, molybdenum, tungsten, indium, silver, calcium, and any combination thereof.

137. A thin film transistor according to claim 135, wherein the gate electrodes are made of a material of a high electron work function and selected from the list comprising nickel, gold, platinum, lead, ITO, and any combination thereof.

138. A thin film transistor according to claim 120, wherein said gate electrodes are in the range between 30 nm and 500 nm thick and are produced by a process selected from the group comprising evaporation, sputtering, chemical vapour deposition, electrodeposition, spin coating, electrolyses plating, printing and any combination thereof.

139. A thin film transistor according to claim 124, wherein material of said insulator layer is selected from the group comprising barium strontium titanate, barium zirconate titanate, lead zirconate titanate, lead lanthanum titanate, barium titanate, strontium titanate, barium magnesium fluoride, tantalum pentoxide, titanium dioxide, yttrium trioxide, silicon dioxide (SiO₂), silicon nitride (Si₃N₄), aluminium oxide (Al₂O₃), hafnium oxide (HfO₂), zirconium silicate, hafnium silicate, hafnium silicate oxynitride, titanium oxide, tantalum oxide, alumsilicate, carbon, carbon-doped silicon dioxide, and any combination thereof.

140. A thin film transistor according to claim 124, wherein said insulator layer has a thickness in the range between approximately 1 and 1000 nm.

141. A thin film transistor according to claim 124, wherein said insulator layer is produced by a process selected from the list comprising sputtering, chemical vapour deposition, sol gel coating, evaporation and laser ablation deposition.

142. A thin film transistor according to claim 120, wherein at least one electrically conductive gate electrode is a multilayer system comprising layers made of different conducting materials, wherein the conducting material is selected from the list comprising copper, gold, silver, zinc, tin, indium, aluminium, titanium, poly-silicon, carbon-based layer as a semi-metal conductor, and any combination thereof.

143. A thin film transistor according to claim 120, wherein at least one electrically conductive source or drain electrode is a multilayer system comprising layers made of different conducting materials.

144. A carbon-based layer comprising
predominantly planar graphene-like structures,
wherein the layer possesses conductivity, and
the thickness of the layer is in the range from approximately 1 to 1000 nm.

145. A carbon-based layer according to claim 144, wherein the graphene-like structures have form of planar graphene-like nanoribbons which are predominantly continuous within the entire carbon-based layer and the planes of said nanoribbons are oriented predominantly perpendicularly to the carbon-based layer surface.

146. A carbon-based layer according to claim 144, wherein the graphene-like structures have form of planar graphene-like sheets which are predominantly continuous within the entire carbon-based layer, and the planes of said sheets are oriented predominantly parallel to the carbon-based layer surface.

147. A carbon-based layer according to claim 144, which possesses an optical anisotropy.

148. A carbon-based layer according to claim 144, which possesses anisotropy of conductivity.

149. A carbon-based layer according to claim 144, wherein the graphene-like structures are globally ordered within the entire carbon-based layer, and wherein a distance between planes of the graphene-like structures approximately equals to 3.5±0.1 Å.

150. A carbon-based layer according to claim 146, wherein the width of the graphene-like nanoribbons provides the carbon-based layer with semiconductor properties due to the forming of an energy bandgap, and the carbon-base layer possesses n-type or p-type conductivity.

151. A carbon-based layer according to claim 144, which possesses metal-type conductivity.

152. A carbon-based layer according to claim 151, wherein the resistivity of the carbon-based layer material is in the range approximately from 10⁻³ to 10⁻⁷ Ohm*cm and smaller.

153. A method of producing a carbon-based layer on a substrate, which comprises the following steps:
(a) application of a solution of one π-conjugated organic compound of the general structural formula I or a combination of such organic compounds: 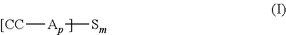
where CC is a predominantly planar carbon-conjugated core;
A is an hetero-atomic group;
p is 0, 1, 2, 3, 4, 5, 6, 7, or 8;
Sₘ is a set of substituents providing a solubility of the organic compound; and
m is a number of S-type substituents in the set Sₘ which equals to 0, 1, 2, 3, 4, 5, 6, 7, or 8;
b) drying with formation of a solid precursor layer, and
(c) formation of the carbon-based layer,
wherein said formation processes is characterized by a level of vacuum, a composition and pressure of ambient gas, and a time dependence of a temperature which are selected so as to ensure a creation of predominantly planar graphene-like structures in the carbon-based layer,
wherein at least one graphene-like structure possesses conductivity and is predominantly continuous within the entire carbon-based layer, and
wherein thickness of the carbon-based layer is in the range from approximately 1 nm to 1000 nm.

154. A method according to claim 153, wherein the predominantly planar carbon-conjugated core (CC), the substituent providing solubility (S), and the S-substituent are selected so that the graphene-like structures have form of planar graphene-like nanoribbons, the planes of which are oriented predominantly perpendicularly to the carbon-based layer surface.

155. A method according to claim 153, wherein the predominantly planar carbon-conjugated core (CC), the substituent providing solubility (S), and the S-substituent are selected so that the graphene-like structures have form of planar graphene-like sheets the planes of which are oriented predominantly parallel to the carbon-based layer surface.

156. A method according to claim 153, wherein the ambient gas comprises chemical elements selected from the list comprising hydrogen, fluorine, arsenic, boron, carbon tetrachloride, halogens, halogenated hydrocarbons, and any combination thereof.

157. A method according to claim 153, wherein said organic compound comprises fragments selected from the group comprising following structures 31, 47, 48 and 49

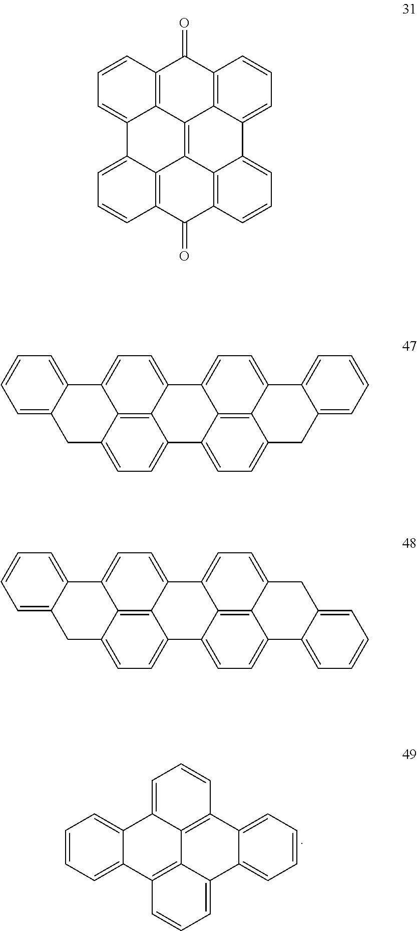

158. A method according to claim 153, wherein the formation step is carried out so as to ensure 1) partial pyrolysis of the organic compound with at least partial removing of substituents, hetero-atomic and solubility groups from the solid precursor layer, and 2) fusion of the carbon-conjugated residues.

159. A method according to claim 158, wherein the pyrolysis temperature is in the range between approximately 150 and 650 degrees C.

160. A method according to claim 158, wherein the fusion temperature is in the range between approximately 500 and 2000 degrees C.

161. A method according to claim 158, wherein the formation step is carried out without heating or under moderate heating (less than 500 degrees C.) under the action of gas-phase or liquid phase environment containing molecules which are sources of free radicals or benzyne fragments.

162. A method according to claim 161, wherein the said formation step is further accompanied by applying an external action upon the carbon-based layer stimulating low-temperature carbonization process of the graphene-like carbon-based structures.

163. A method according to claim 158, wherein the level of vacuum, the composition and pressure of ambient gas, the duration and temperature of the pyrolysis, the duration and temperature of the fusion, parameters of external actions (UV or IR light spectral characteristics) are selected so that the resistivity of the carbon-based layer material is in one of the ranges selected from the list comprising the range of approximately from 1 to 10⁻³ Ohm*cm, 10⁻³ to 10⁻⁵ Ohm*cm, 10⁻⁵ to 10⁻⁷ Ohm*cm, and less than 10⁻⁷ Ohm*cm.

164. A method according to claim 153, further comprising the step of removing the substrate by one of the methods selected from the list comprising wet chemical etching, dry chemical etching, plasma etching, laser etching, grinding, and any combination thereof.

165. A method according to claim 153, wherein the set Sₘ comprises identical substituents providing solubility of the organic compound.

166. A method according to claim 153, wherein the set Sₘ comprises more than two substituents providing solubility of the organic compound and at least one substituent is different from the other or others.

167. A method according to claim 153, wherein the steps (a), (b) and (c) are consistently repeated two or more times, and sequential carbon-based layers are formed using solutions based on the same or different organic compounds or their combinations.

168. A method according to claim 153, wherein at least one 7-conjugated organic compound further comprises a set of substituents D_{Z}, wherein D is independently selected from a list comprising —NO₂, —Cl, —Br, —F, —CF₃, —CN, —OH, —OCH₃, —OC₂H₅, —OCOCH₃, —OCN, —SCN, —NH₂, —NHCOCH₃, and —CONH₂, where z is a number of D-type substituents and equals to 0, 1, 2, 3 or 4.

169. A method of producing a carbon-based layer on a substrate, which comprises the following steps:
(a) preparation of a solution of one 7-conjugated organic compound of the general structural formula II or a combination of such organic compounds capable of forming supramolecules: 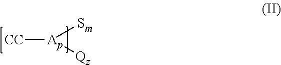
where CC is a predominantly planar carbon-conjugated core;
A is an hetero-atomic group;
p is 0, 1, 2, 3, 4, 5, 6, 7, or 8;
S and Q are substituents,
where S is a substituent providing a solubility of the organic compound in suitable solvent and Q is a substituent which produces reaction centres selected from the list comprising
free radicals and benzyne fragments on the predominantly planar carbon-conjugated cores
after elimination this substituent during a subsequent step (d);
m is 0, 1, 2, 3, 4, 5, 6, 7, or 8; and
z is 0, 1, 2, 3 or 4;
(b) deposition of a layer of the solution on the substrate followed by an external alignment action upon the solution in order to ensure preferred alignment of the supramolecules;
(c) drying to form a solid layer comprising graphene-like carbon-based structures; and
(d) applying an external action upon the solid layer stimulating carbonization of the graphene-like carbon-based structures.

170. A method according to claim 169, wherein the substituent Q is selected from the list comprising halogens Cl, Br, and I.

171. A method according to claim 169, wherein said deposition step is carried out using means selected from the list comprising spray-coating, a Mayer rod technique, a slot-die application, extrusion, roll coating, curtain coating, knife coating, and printing.

172. A method according to claim 169, wherein the external alignment action upon the surface of the solution layer is produced by directed mechanical motion of at least one aligning instrument selected from the list comprising a knife, a cylindrical wiper, a flat plate and any other instrument oriented parallel to the deposited solution layer surface, whereby the distance from the substrate surface to the edge of the aligning instrument is preset so as to obtain a solid layer comprising graphene-like carbon-based structures of a required thickness.

173. A method according to claim 169, wherein the external alignment action is performed using means selected from the list comprising a heated instrument, application of an external electric field to the deposited solution layer, application of an external magnetic field to the deposited solution layer, application of an external electric and magnetic field to the system with simultaneous heating and illuminating the deposited solution layer with at least one coherent laser beam, a thermal treatment and an ultraviolet irradiation.

174. A method according to claim 173, wherein the thermal treatment is carried out at a temperature not exceeding the fusion temperature of the substrate material.
